(19) United States
(12) Patent Application Publication
(10) Pub. No.: US 2024/0352312 A1
(43) Pub. Date: Oct. 24, 2024

(54) MICROEMULSION TEMPLATE ASSISTED SYNTHESIS OF CADMIUM-FREE NEAR-INFRARED QUANTUM DOTS BASED ON I-III-VI TERNARY SEMICONDUCTORS

(71) Applicant: Quantum Technology Group, Woburn, MA (US)

(72) Inventor: Jun Wang, Woburn, MA (US)

(21) Appl. No.: 18/573,651

(22) PCT Filed: Jun. 24, 2022
(86) PCT No.: PCT/US2022/034875

§ 371 Date: Dec. 22, 2023

Related U.S. Application Data
(60) Provisional application No. 63/215,186, filed on Jun. 25, 2021.

(51) Int. Cl. C09K 11/62; B82Y 20/00; B82Y 40/00; C09K 11/02; H01L 33/50

(52) U.S. Cl. CPC C09K 11/623; C09K 11/025; B82Y 20/00; B82Y 40/00; H01L 33/502; H01L 33/505; H01L 2933/0041

(57) ABSTRACT

A method for making ternary core-shell semiconductor nanoparticles includes providing an emulsion including droplets dispersed in a continuous phase of a non-polar solvent. The droplets include a solution of ions of a Group I element and ions of a Group III element in a polar solvent, and are encapsulated by an interfacially active material. The emulsion is exposed to ions of a Group VI element to cause a reaction, thereby forming nanoparticles in the droplets. The nanoparticles in the droplets are with a first precursor to grow a shell on the nanoparticles, thereby forming core-shell nanoparticles. The core-shell nanoparticles are extracted from the emulsion; thermally annealed; and reacted with a second precursor to further grow the shell on the nanoparticles, thereby forming ternary core-shell semiconductor nanoparticles.

### CROSS-REFERENCE TO RELATED APPLICATIONS

This application claims the benefit of priority to U.S. Provisional Application No. 63/215,186, filed on Jun. 25, 2021, the contents of which are incorporated here by reference in their entirety.

### BACKGROUND

Biomedical imaging is used in clinical diagnosis, therapy assessment, patient treatment, and surgical operations, allowing observation of pathological and physiological events with human diseases. Fluorescence imaging using near infrared (NIR) fluorophore, e.g., with fluorescence in the range of 700 nm to 900 nm, enables imaging of physiological, metabolic and molecular function in vivo. Imaging using NIR fluorophores is relevant for cancer detection and diagnosis and surgical resection, diagnosis of diseases such as neurological disorders, e.g., Alzheimer's disease, and in cardiovascular and plastic and reconstructive surgeries.

### SUMMARY

We describe here approaches to synthesis of cadmium-free near-infrared core-shell quantum dots based on I-III-VI ternary semiconductors. For instance, CuInS₂, CuInSe₂, AgInS₂, or AgInSe₂ quantum dot cores coated with ZnS or ZnSe shells can be produced. These quantum dots are biocompatible and fluoresce in the near infrared (NIR), e.g., with fluorescence emission wavelengths in the range of 650 to 840 nm. The synthesis processes described here provide mechanisms for precise control of the size, size distribution, and composition of the quantum dots (e.g., the quantum dot cores), all of which affect the fluorescence spectrum of the quantum dots.

The synthesis processes described here separate the nucleation and growth of the core of the quantum dots from further growth, annealing and shelling of the core quantum dots, enabling precise control of the size and composition of the resulting nanoparticles and hence control over the NIR emission spectrum of the nanoparticles. A microemulsion template assisted approach to nucleation and growth of the cores is used, followed by annealing and growth of the shell of the core quantum dots.

The resulting core-shell NIR quantum dots can be oil soluble or water soluble, depending on, e.g., the annealing approach and the identity of the surface ligands used to functionalize the core-shell quantum dots.

NIR quantum dots soluble in organic (e.g., hydrophobic) solvents (e.g., quantum dots coated with hydrophobic ligands) are useful in the context of, e.g., photovoltaic applications. Water soluble NIR quantum dots (e.g., quantum dots coated with hydrophilic ligands with functional groups which allow conjugation with various types of biomolecules) can be used in biological and medical applications such as biomedical diagnosis, drug delivery, and surgical assistance applications

In an aspect, a method for making ternary core-shell semiconductor nanoparticles includes providing an emulsion including droplets dispersed in a continuous phase of a non-polar solvent. The droplets include a solution of ions of a Group I element and ions of a Group III element in a polar solvent, and in which the droplets are encapsulated by an interfacially active material. The method includes exposing the emulsion to ions of a Group VI element to cause the ions of a Group VI element to react with the ions of the Group I element and ions of the Group III element in the droplets to form nanoparticles in the droplets; reacting the nanoparticles in the droplets with a first precursor to grow a shell on the nanoparticles, thereby forming core-shell nanoparticles; extracting the core-shell nanoparticles from the emulsion; thermally annealing the core-shell nanoparticles; and reacting the annealed core-shell nanoparticles with a second precursor to further grow the shell on the nanoparticles, thereby forming ternary core-shell semiconductor nanoparticles.

Embodiments can include one or any combination of two or more of the following features.

The method includes dissolving a first reactant and a second reactant in the polar solvent to form the solution of the ions of a Group I element and the ions of a Group III element. The first reactant includes a Group I element-containing compound and the second reactant includes a Group III element-containing compound. The first reactant includes a salt of the Group I element. The first reactant includes Copper (I) iodide (CuI), Copper (I) chloride (CuCl), Copper (I) bromide (CuBr), Cu(I) acetate (Cu(Ac)), Silver nitrate (Ag(NO₃)), Silver acetate (Ag(Ac)), or Silver sulfate (Ag₂(SO₄)). The second reactant includes Indium (III) acetate (In(Ac)₃), Indium (III) chloride (InCl₃), Indium (III) sulfate (In₂(SO₄)₃) or Indium (III) nitrate (In(NO₃)₃). The method includes adjusting the pH of the polar solvent to dissolve the first reactant and the second reactant in the polar solvent. Dissolving the first reactant and the second reactant in the polar solvent includes: dissolving the first reactant in a basic or acidic solution of the polar solvent; dissolving the second reactant in an acidic or basic solution of the polar solvent; and combining the basic solution with the dissolved first reactant and the acidic solution with the dissolved second reactant to form the solution of the ions of a Group I element and the ions of a Group III element.

The ions of the Group I element include ions of Cu or Ag.

The ions of the Group III element include ions of In or Ga.

The interfacially active material includes an amphiphilic block copolymer, a surfactant, a water-dispersible polymer, an amphiphilic molecule, a solid particle, or a solvent-swollen particle.

The nanoparticles have a composition ABXy, where A is the Group I element, B is the Group III element, and X is the Group VI element.

Exposing the emulsion to ions of the Group VI element includes contacting the emulsion with a gas, a solid, or an aqueous solution containing a Group VI element-containing compound. The gas, solid, or aqueous solution containing the Group VI element-containing compound includes a hydride of the Group VI element. The Group VI element-containing compound is soluble in a polar solvent.

The Group VI element includes S, Se, or Te.

Reacting the nanoparticles in the droplets with the first precursor includes exposing the emulsion to a precursor to the shell. The precursor to the shell includes a precursor to ZnS or ZnSe. The precursor to the shell includes a Zn⁺ precursor solution.

The method includes functionalizing the core-shell nanoparticles with hydrophilic surface ligands.

The method includes functionalizing the core-shell nanoparticles with hydrophobic surface ligands. The method includes exchanging the hydrophobic surface ligands for hydrophilic surface ligands following growth of the shell on the nanoparticles.

Thermally annealing the core-shell nanoparticles includes annealing the core-shell nanoparticles in a batch process.

Thermally annealing the core-shell nanoparticles includes exposing the nanoparticles to multiple cycles of heating and cooling. Thermally annealing the core-shell nanoparticles includes flowing an aqueous solution of the core-shell nanoparticles through a flow channel. The method includes applying heating fluid and cooling fluid to alternating portions of the flow channel to expose the nanoparticles to the multiple cycles of heating and cooling.

Reacting the annealed core-shell nanoparticles with the second precursor includes reacting the annealed core-shell nanoparticles with Zn²⁺ ions. Reacting the annealed core-shell nanoparticles with the second precursor includes dispersing droplets of a solution of the annealed core-shell nanoparticles and Zn²⁺ ions in a dispersant gas.

The method includes reacting the annealed core-shell nanoparticles with the second precursor in a tubular coiled reactor.

The ternary core-shell semiconductor nanoparticles have a fluorescence emission wavelength of between 650 nm and 840 nm.

The ternary core-shell semiconductor nanoparticles have a fluorescence emission spectrum with a full width at half maximum of less than or equal to 100 nm.

The ternary core-shell semiconductor nanoparticles have a quantum yield of at least 40% in an aqueous solvent.

In an aspect, a method for making ternary core-shell semiconductor nanoparticles includes providing an emulsion including droplets dispersed in a first solvent. The droplets include a solution of ions of a Group I element and ions of a Group III element in a second solvent, and in which the droplets are encapsulated by an interfacially active material, and in which the first solvent is immiscible with the second solvent. The method includes exposing the emulsion to ions of a Group VI element to cause the ions of the Group VI element to react with the ions of the Group I element and ions of the Group III element in the droplets to form nanoparticles in the droplets; reacting the nanoparticles in the droplets with a first precursor to grow a shell on the nanoparticles, thereby forming core-shell nanoparticles; and extracting the core-shell nanoparticles from the emulsion.

Embodiments can include one or any combination of two or more of the following features.

The core of the core-shell nanoparticles has a composition ABXy, where A is the Group I element, B is the Group III element, and X is the Group VI element. The core of the core-shell nanoparticles has a composition CuInS₂, CuInSe₂, AgInS₂, or AgInSe₂.

The first solvent includes a polar solvent and the second solvent includes a non-polar solvent.

The interfacially active material includes an amphiphilic block copolymer, a surfactant, a water-dispersible polymer, an amphiphilic molecule, a solid particle, or a solvent-swollen particle.

Exposing the emulsion to ions of the Group VI element includes contacting the emulsion with a gas, a solid, or an aqueous solution containing a Group VI element-containing compound. Contacting the emulsion with the gas containing the Group VI element-containing compound includes bubbling the gas into the emulsion.

Reacting the nanoparticles in the droplets with the precursor of higher band gap energy semiconductor includes exposing the emulsion to a precursor to the shell. The precursor to the shell includes a precursor to ZnS or ZnSe. The precursor to the shell includes a Zn²⁺ precursor solution.

Reacting the nanoparticles in the droplets with the first precursor causes the shell to grow to a thickness of 0.3 nm to 1 nm.

The method includes functionalizing the core-shell nanoparticles with hydrophilic surface ligands.

The method includes functionalizing the core-shell nanoparticles with hydrophobic surface ligands.

In an aspect, a method for making ternary core-shell semiconductor nanoparticles, the method includes extracting core-shell nanoparticles from an emulsion comprising droplets of a first solvent dispersed in a second solvent, in which the nanoparticles are contained in the droplets and in which the droplets are encapsulated by an interfacially active material, and in which the nanoparticles comprise a core coated with a shell, in which the core of the core-shell nanoparticles has a composition ABXy, where A is a Group I element, B is a Group III element, and X is a Group VI element; thermally annealing the core-shell nanoparticles, comprising exposing the nanoparticles to multiple cycles of heating and cooling; and reacting the annealed core-shell nanoparticles with a precursor to increase the thickness of the shell of the nanoparticles.

In an aspect, a method for making ternary core-shell semiconductor nanoparticles includes extracting core-shell nanoparticles from an emulsion including droplets of a first solvent dispersed in a second solvent. The nanoparticles are contained in the droplets and in which the droplets are encapsulated by an interfacially active material, and in which the nanoparticles include a core coated with a shell. The method includes thermally annealing the core-shell nanoparticles, including exposing the nanoparticles to multiple cycles of heating and cooling; and reacting the annealed core-shell nanoparticles with a precursor to increase the thickness of the shell of the nanoparticles.

Embodiments can include one or any combination of two or more of the following features.

The core of the core-shell nanoparticles has a composition ABXy, where A is a Group I element, B is a Group III element, and X is a Group VI element. The core of the core-shell nanoparticles has a composition CuInS₂, CuInSe₂, AgInS₂, or AgInSe₂.

The shell of the core-shell nanoparticles has a composition of ZnS or ZnSe.

The core-shell nanoparticles extracted from the emulsion are water soluble.

The core-shell nanoparticles extracted from the emulsion are soluble in an organic solvent.

Thermally annealing the core-shell nanoparticles includes flowing an aqueous solution of the core-shell nanoparticles through a flow channel. The method includes applying heating fluid and cooling fluid to alternating portions of the flow channel to expose the nanoparticles to the multiple cycles of heating and cooling.

Thermally annealing the core-shell nanoparticles includes alternately heating the core-shell nanoparticles to a temperature of between 200° C. and 250° C., and cooling the core-shell nanoparticles to a temperature of between 10° C. and 40° C.

Thermally annealing the core-shell nanoparticles includes exposing the nanoparticles to cycles of heating and cooling with a frequency of between 0.0001 Hz and 1 Hz.

Reacting the annealed core-shell nanoparticles with the second precursor includes reacting the annealed core-shell nanoparticles with Zn²⁺ ions. Reacting the annealed core-shell nanoparticles with the second precursor includes dispersing droplets of a solution of the annealed core-shell nanoparticles and Zn²⁺ ions in a feeding solution. The feeding solution acts as a source of sulfur for the shell of the nanoparticles.

The method includes reacting the annealed core-shell nanoparticles with the second precursor in a tubular coiled reactor.

In an aspect, a composition includes an emulsion containing droplets of a first solvent dispersed in a second solvent; an interfacially active material encapsulating each droplet of the emulsion; and a core-shell nanoparticle contained in each of at least some of the droplets. The core of each core-shell nanoparticles has a composition ABXy, where A is a Group I element, B is a Group III element, and X is a Group VI element.

Embodiments can include one or any combination of two or more of the following features.

The core of the core-shell nanoparticles has a composition CuInS₂, CuInSe₂, AgInS₂, or AgInSe₂.

The shell of the core-shell nanoparticles includes ZnS or ZnSe.

A thickness of the shell of the core-shell nanoparticles is between 0.3 nm and 1 nm.

A band gap of the shell of the core-shell nanoparticles is larger than a band gap of the core of the core-shell nanoparticles.

The first solvent is a polar solvent and the second solvent is a non-polar solvent.

The interfacially active material includes an amphiphilic block copolymer, a surfactant, a water-dispersible polymer, an amphiphilic molecule, a solid particle, or a solvent-swollen particle.

The core of the core-shell nanoparticles and the core-shell nanoparticles both have a fluorescence emission wavelength of between 650 nm and 840 nm.

A diameter of each droplet is between 30 nm and 40 nm.

In an aspect, a system for making ternary core-shell semiconductor nanoparticles includes a reaction vessel configured to receive an emulsion including droplets dispersed in a first solvent. The droplets include a solution of ions of a Group I element and ions of a Group III element in a second solvent, and in which the droplets are encapsulated by an interfacially active material. The system includes a source of inert gas fluidically connected to the reaction vessel. The system includes a source of a gaseous Group VI element-containing compound fluidically connected to the reaction vessel; and a flow controller configured to control the flow of the gaseous Group VI element-containing compound into the reaction vessel. When the gaseous Group VI element-containing compound is flowed into the reaction vessel, the ions of the Group I element and the ions of the Group III element react with ions of the Group VI element to form nanoparticles in the droplets.

In an aspect, a system for synthesizing ternary core-shell semiconductor nanoparticles includes a first reactor including a first fluid flow channel. An inlet of the fluid flow channel is configured to receive droplets of an aqueous solution dispersed in a carrier gas, the droplets of aqueous solution having nanoparticles contained therein. The first reactor includes a heating subsystem configured to heat first portions of the fluid flow channel; and a cooling subsystem configured to cool second portions of the fluid flow channel. The fluid flow channel includes multiple first portions and multiple second portions in an alternating arrangement. The system includes a second reactor including a second fluid flow channel having inlets configured to receive the aqueous solution of nanoparticles from the first reactor, a precursor solution, and a dispersant gas; and a coiled reactor configured to receive droplets of the aqueous solution of nanoparticles and the precursor solution dispersed in the dispersant gas.

Embodiments can include one or any combination of two or more of the following features.

The system includes a spectrometer disposed along the second fluid flow channel upstream of the coiled reactor.

The system includes a spectrometer disposed along the second fluid flow channel downstream of the coiled reactor.

The system includes a flow controller configured to control a flow rate of the aqueous solution of nanoparticles.

The system includes a flow controller configured to control a flow rate of the precursor solution.

The system includes a flow controller configured to control a flow rate of the dispersant gas.

The approaches described here can have one or more of the following advantages. The synthesis approaches described here can produce water soluble, biocompatible core-shell quantum dots with high fluorescence intensity, high quantum yield, and good photostability. For instance, core-shell quantum dots synthesized by the approaches described here can fluoresce in the near infrared and are free of heavy metals such as cadmium, thereby meeting criteria for diagnostic probes. The synthesis process produces large quantities of monodisperse quantum dots and enables precise control over the composition, size, and size distribution of the quantum dots. The synthesis process is scalable.

The details of one or more implementations are set forth in the accompanying drawings and the description below. Other features and advantages will be apparent from the description and drawings, and from the claims.

### BRIEF DESCRIPTION OF DRAWINGS

FIG. 1 is a schematic diagram of a process for synthesizing cadmium-free near-infrared quantum dots based on I-III-VI ternary semiconductors.

FIG. 2 is a schematic diagram of a microemulsion template approach for synthesis of quantum dot cores.

FIG. 3 is a diagram of a reactor system for synthesis of quantum dot cores.

FIG. 4 is a diagram of a microfluidic system for annealing of quantum dots.

FIG. 5 is a diagram of a microfluidic system.

FIG. 6 is a flow chart.

FIGS. 7 and 8 are plots of emission spectra for CuInS₂ quantum dot cores.

FIG. 9 is a plot of emission intensity for CuInS₂ quantum dot cores.

FIG. 10 is a plot of normalized emission spectra for CuInS₂ quantum dot cores with various precursor concentrations.

FIGS. 11A and 11B are transmission electron microscopy (TEM) images of CuInS₂ quantum dot cores.

FIG. 12A is a plot of normalized excitation, absorption, and emission spectra for CuInS₂ quantum dot cores.

FIG. 12B is a plot of emission spectra of CuInS₂ quantum dot cores synthesized with different precursor concentrations.

FIG. 12C is a plot of the peak emission wavelength of CuInS₂ quantum dot cores synthesized with different precursor concentrations.

FIG. 13A is a plot of the emission intensity amplification of CuInS₂ quantum dot cores with and without ZnS shells.

FIG. 13B is plots of emission spectra of CuInS₂ quantum dot cores with and without ZnS shells.

FIG. 13C is a plot of emission spectra of CuInS₂ quantum dot cores synthesized with different precursor concentrations and capped with ZnS shells.

FIG. 14 is a plot of emission spectra of AgInS₂ quantum dot cores synthesized with different In³⁺ precursors.

FIG. 15A is a plot of emission spectra of AgInS₂ quantum dot cores synthesized with different precursor concentrations.

FIG. 15B is a plot of normalized absorption, excitation, and emission spectra for AgInS₂ quantum dot cores.

FIG. 16A is a plot of the emission intensity amplification of AgInS₂ quantum dot cores with and without ZnS shells.

FIG. 16B is a plot of emission spectra of AgInS₂ quantum dot cores with ZnS shells.

FIG. 16C is plots of emission spectra of AgInS₂ quantum dot cores synthesized with different precursor concentrations and capped with ZnS shells.

FIG. 17A is a plot of emission spectra of AgInS₂ quantum dot cores synthesized with different precursor concentrations.

FIG. 17B is a plot of normalized excitation and emission spectra of AgInS₂ quantum dot cores synthesized with different precursor concentrations.

FIG. 18A is a plot of the emission intensity amplification of AgInS₂ quantum dot cores with and without ZnS shells.

FIG. 18B is a plot of emission spectra of AgInS₂ quantum dot cores with and without ZnS shells.

FIG. 19A is a plot of emission spectra of AgInS₂ quantum dot cores without shells and shelled with ZnS shells under different shelling conditions.

FIG. 19B is a plot of the relative emission intensity of AgInS₂ quantum dot cores without shells and shelled with ZnS shells under different shelling conditions.

FIG. 19C is a plot of normalized emission spectra of AgInS₂ quantum dot cores shelled with ZnS shells.

FIG. 20A is a plot of emission spectra for AgInS₂ quantum dot cores synthesized with various Ag¹⁺/In³⁺ ratios.

FIG. 20B is a plot of the peak emission wavelength of AgInS₂ quantum dot cores synthesized with different precursor concentrations and various Ag¹⁺/In³⁺ ratios.

FIG. 20C is an excitation scanning plot of AgInS₂ quantum dot cores synthesized with various Ag¹⁺/In³⁺ ratios.

### DETAILED DESCRIPTION

We describe here approaches to synthesis of cadmium-free near-infrared core-shell quantum dots (also sometimes referred to as nanoparticles) based on I-III-VI ternary semiconductors. For instance, CuInS₂, CuInSe₂, AgInS₂, or AgInSe₂ quantum dot cores coated with ZnS or ZnSe shells can be produced. These core-shell quantum dots are biocompatible and fluoresce in the near infrared (NIR), e.g., with fluorescence emission wavelengths in the range of 650 to 840 nm. The synthesis processes described here provide mechanisms for precise control of the size, size distribution, and composition of the quantum dots (e.g., the quantum dot cores), all of which affect the fluorescence spectrum of the core-shell quantum dots.

The synthesis processes described here separate the nucleation and growth of the core of the quantum dots from further growth, annealing, and shelling of the quantum dot cores, enabling precise control of the size and composition of the resulting core-shell quantum dots and hence control over their NIR emission spectrum. A microemulsion template assisted approach to nucleation and growth of the cores is used, followed by annealing and growth of the shell. The resulting core-shell NIR quantum dots can be soluble in water or in hydrophobic solvents and have a fluorescence emission spectrum in the NIR range.

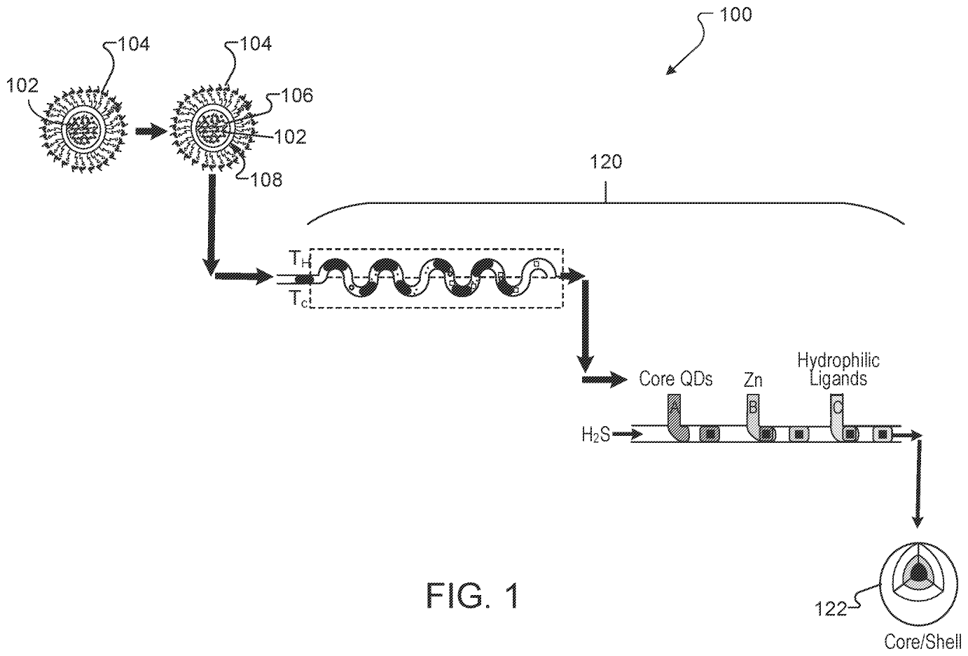

FIG. 1 is a schematic diagram of a process 100 for synthesizing nanoparticles, e.g., cadmium-free near-infrared core-shell quantum dots based on I-III-VI ternary semiconductors. The process 100 of FIG. 1 separates the nucleation and growth of the core from annealing and growth of the shell. In this process, quantum dot cores 102 (sometimes also referred to as nanoparticles or core nanoparticles) are synthesized using microemulsion templates 104 in a gas-liquid contacting reactor system. The size, size distribution, and composition of the quantum dot cores 102 is controllable, enabling control of the emission wavelength and fluorescence intensity of the resulting quantum dots. For instance, the size, size distribution, and composition of the quantum dot cores 102 can be controlled such that the resulting quantum dots have an emission wavelength in the near infrared, e.g., in the range of 650-840 nm, and with a narrow size distribution, which gives rise to a narrow width of the emission spectrum. For instance, the full width at half maximum (FWHM) of the fluorescence emission spectrum can be less than or equal to about 100 nm, e.g., between 10 nm and 100 nm, between 20 nm and 80 nm, or between 30 nm and 60 nm. The quantum dot cores can have a high quantum yield, e.g., a quantum yield of greater than 40%, e.g., between 40% and 80%, between 40% and 70%, between 40% and 60%, or between 40% and 50%.

I-III-VI semiconductor quantum dot cores are composed of three chemical elements belonging to groups I, III, and VI of the periodic table, e.g., two metals and a chalcogen. The quantum dot cores can have the general composition ABX_{y}, where A is a Group I element such as Cu or Ag; B is a Group III element such as In or Ga; and X is a Group VI element such as S, Se, or Te. Specific example compositions for I-III-VI quantum dots that can be synthesized by the approaches described here include CuInS₂, CuInSe₂, AgInS₂, or AgInSe₂.

The quantum dot cores 102 in the microemulsion templates 104 are coated with a thin shell 106 of a high band gap material, such as ZnS or ZnSe, to produce thin-shelled quantum dots 108 (sometimes also referred to as core-shell nanoparticles). By high band gap material, we mean that the band gap of the shell 106 is larger than the band gap of the core 102. In some examples, the thin-shelled quantum dots 108, still in the microemulsion templates 104, are capped with hydrophilic surface ligands, rendering the thin-shelled quantum dots 108 water soluble and facilitating their extraction from the microemulsion. In some examples, the thin-shelled quantum dots 108 in the microemulsion templates 104 are capped with hydrophobic surface ligands, rendering the thin-shelled quantum dots 108 soluble in hydrophobic solvents, e.g., organic solvents such as hexane and facilitating their extraction from the microemulsion.

Once extracted from the microemulsion, the thin-shelled quantum dots 108 are thermally annealed at high temperature and the shell is grown to a larger thickness to produce core-shell quantum dots 122. The thicker shell is the same material as the thin shell of the thin-shelled quantum dots 108, e.g., a high band gap material such as ZnS or ZnSe. The annealing and growth of a thick shell stabilizes the core-shell quantum dots and removes crystal defects, thereby enhancing their quantum yield. In the example of FIG. 1, the annealing and shell growth processes are performed in a continuous, segmented flow micro-reactor system 120. In some examples, the annealing and shell growth processes are performed in a batch reactor at high temperature. The annealed core-shell quantum dots can be dispersed in an appropriate solvent (e.g., water or an organic solvent, depending on the nature of the ligands functionalizing the quantum dots), or mixed with polymers to form a powder. In some examples, core-shell quantum dots functionalized with hydrophobic ligands can be surface modified by ligand exchange to form water soluble core-shell quantum dots, e.g., quantum dots with functional groups capable of bio-conjugation.

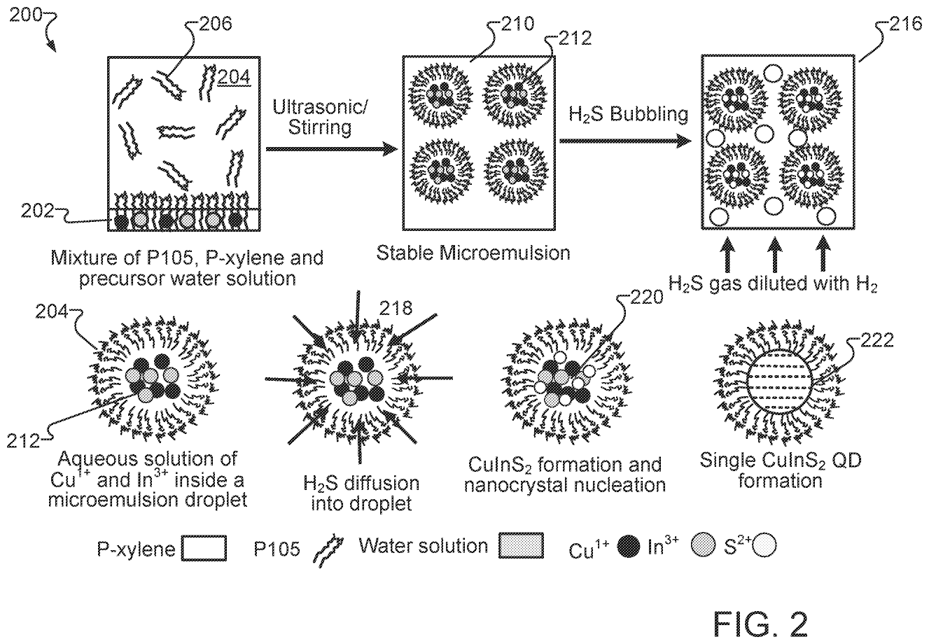

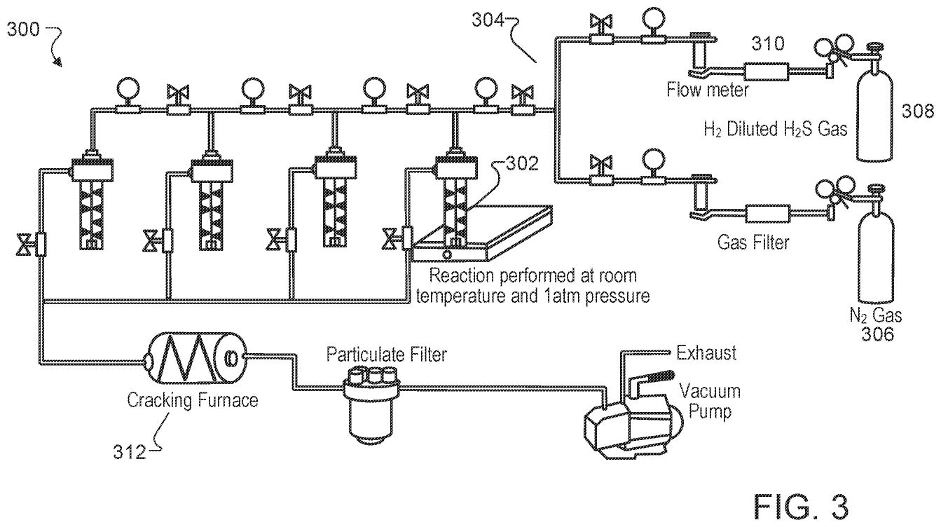

Referring to FIG. 2, quantum dot cores based on I-III-VI ternary semiconductors are synthesized using a microemulsion template assisted approach 200 with a gas-liquid contacting reactor system (see FIG. 3, discussed infra). This approach enables the size, size distribution, and composition of the quantum dot cores to be controlled, thus enabling control over the emission wavelength and fluorescence intensity of the resulting quantum dot cores. For instance, this approach can be used to synthesize quantum dot cores having an emission wavelength in the near infrared, e.g., in the range of 650-840 nm, and with a narrow size distribution. The width of the emission spectrum can be narrow, e.g., the full width at half maximum (FWHM) of the emission spectrum can be less than or equal to about 100 nm.

In a microemulsion template approach to quantum dot core synthesis, the microemulsion templates are formed by self-assembly of ternary systems including a polar solvent, a non-polar solvent, and an interfacially active material, such as surfactants, amphiphilic block copolymers, water-dispersible polymers, amphiphilic molecules, solid particles, or solvent-swollen particles. The templates are formed by self-assembly of the interfacially active material in the presence of the polar solvent and the non-polar solvent in a specified ratio. The shape of the nanostructure material synthesized according to the microemulsion template approach is controlled by the composition of the ternary self-assembled templates. The size of the quantum dot cores and their composition are controlled by the concentration of precursor reactants and the molar ratio of precursor reactants supplied to the templates.

Referring specifically to FIG. 2, first and second precursor reactants (collectively referred to as precursor reactants) are dissolved in a polar solvent to form a precursor reactant solution 202. The first precursor reactant is a compound containing a Group I metal element (e.g., Cu or Ag), such as a salt of a Group I metal (e.g., Copper (I) iodide (CuI), Copper (I) chloride (CuCl), Copper (I) bromide (CuBr), Cu(I) acetate ((Cu(Ac), Silver nitrate (Ag(NO₃)), Silver acetate (Ag(Ac)), or Silver sulfate (Ag₂(SO₄)). The second precursor reactant is a compound containing a Group III metal element (e.g., In or Ga), such Indium (III) acetate (In(Ac)₃), Indium (III) chloride (InCl₃), Indium (III) sulfate (In₂(SO₄)₃, or Indium (III) nitrate (In(NO₃)₃. The concentration of precursor reactant used for core quantum dots synthesis can be in the range of, e.g., 0.001 M up to 2 M, or any suitable concentration at which the microemulsion template is stable. The size of quantum dot cores synthesized using the microemulsion template approach depends on the concentration of precursor reactants in the polar phase and the molar ratio of the precursor reactants. The Group I precursor and Group III precursor can be mixed with equal molar ratio (1:1) or non-equal molar ratio (e.g., 0.5:1.2, 0.6:1.1, 0.8:1.02, or another appropriate molar ratio). For precursors with same concentration, adjusting the molar ratio of Group I/Group III precursors will result in core quantum dots with the same size but different emission wavelength. When the precursor reactants are dissolved, the precursor reactant solution contains ions of the Group I and Group III metals. The precursor reactant solution 202 is mixed with a non-polar solvent 204 and an interfacially active material 206 to form a mixture. The concentration of the interfacially active material can affect formation of a stable spherical microemulsion template that will result in formation of spherical nanoparticles inside microemulsion droplets. For instance, the concentration of the interfacially active material can be in the range of, e.g., about 15 wt % to about 50 wt %, e.g., about 15 wt %, about 20 wt %, about 25 wt %, about 30 wt %, about 35 wt %, about 40 wt %, about 45 wt %, or about 50 wt %. The concentration of the nonpolar phase can be in the range of, e.g., about 70 wt % to about 85 wt %, e.g., about 70 wt %, about 75 wt %, about 80 wt %, or about 85 wt %. The concentration of the polar phase can be in the range of, e.g., about 2 wt % and about 11 wt %, e.g., about 2 wt %, about 4 wt %, about 6 wt %, about 8 wt %, about 10 wt %, or about 11 wt %.

Suitable polar solvents include, e.g., water or formamide. Suitable non-polar solvents are immiscible with the polar solvent and include, e.g., organic solvents such as alkenes, e.g., p-xylene; alkanes, e.g., n-hexane, n-heptane, or n-octane. The interfacially active material can include surfactants, amphiphilic block copolymers, water-dispersible polymers, amphiphilic molecules, solid particles, or solvent-swollen particles. Suitable amphiphilic block copolymers include, e.g., block copolymers composed of poly (ethylene oxide) (PEO) and poly (propylene oxide) (PPO), such as PEO-PPO-PEO; block copolymers made by joining PEO or poly (acrylic acid) blocks with polystyrene, polybutylene, or polymethylsiloxane; or other amphiphilic block copolymers. Suitable surfactants include, e.g., natural surfactants (e.g., lipids), synthetic surfactants (e.g., alkylbenzyl sulfonates), ionic surfactants (e.g., sodium dodecyl sulfate), cationic surfactants (e.g., alkyl-trimethylammonium chloride), nonionic surfactants (e.g., alkyl ethoxylates), or zwitterionic surfactants (e.g. betaine). The surfactants can be a single species (e.g., one type of molecule present) or mixtures of species (e.g., mixture of anionic and cationic surfactants, mixture of an ionic surfactant and an aliphatic alcohol). The surfactants can be monodisperse or polydisperse. Suitable water-dispersible polymers can include dextran, guar gum, and gelatine. Suitable solid particles can include silica, aluminum oxide, and titanium oxide. Suitable solvent-swollen particles can include latexes.

In the specific example of FIG. 2, the polar solvent is water and the precursor reactant solution 202 is an aqueous solution of Cu¹⁺ and In³⁺ ions. The surfactant Pluronic® P105 surfactant (BASF Corporation) is the interfacially active material 206 and p-xylene is the non-polar solvent 204.

In some examples, a reagent is added to the polar solvent to increase or decrease the pH of the aqueous solution, thereby promote dissolution of the precursor reactants and increasing the solubility of the metal ions. The reagent can be an acid, such as hydrochloric acid (HCl), or a base, such as ammonia hydroxide (NH₄—OH), that will not interfere with the stability of the microemulsion template droplets (discussed infra). In some examples, each of the precursor reactants is dissolved in its own solution and the two solutions are then mixed. For instance, the Group I precursor reactant can be dissolved in an acidic solution and the Group III precursor reactant can be dissolved in a basic solution. The Group I precursor reactant can also be dissolved in a basic solution and the Group III precursor reactant can be dissolved in an acid solution. One of the Group I precursor reactant and Group III precursor reactant or both of them can be dissolved in a neutral solution, such as DI water.

The mixture is stirred or ultrasonically agitated, yielding an emulsion 210 of the polar solvent dispersed in a continuous phase of the non-polar solvent. The emulsion 210 contains stable droplets 212 of the polar solvent dispersed in the non-polar solvent and encapsulated by the interfacially active material. Each droplet 212 contains a solution (e.g., an aqueous solution) of ions of the Groups I and III metals (e.g., Cu¹⁺ and In³⁺ ions, in the example of FIG. 2) encapsulated in (e.g., surrounded by) the interfacially-active material. In some examples, stirring or agitating the mixture yields an emulsion of the non-polar solvent dispersed in a continuous phase of the polar solvent.

The emulsion 210 is exposed to a Group VI element-containing compound, such as a compound containing S, Se, or Te, e.g., by bubbling a gaseous Group VI element-containing compound into the emulsion 210. The gaseous Group VI element-containing compound can be a Group VI element-containing hydride (e.g., H₂S gas or H₂Se gas) or a gaseous Te-containing compound (e.g., vapors of dimethyl-Te, diethyl-Te, or diisopropyl-Te). The gaseous Group VI element-containing compound can be diluted in a carrier gas with a concentration in a range of, e.g., about 1% to about 10%, e.g., about 1%, about 2%, about 4%, about 6%, about 8%, or about 10%. The carrier gas is a gas that does not react with the ions of the Groups I and III metals, the Group VI element-containing compound, the stable microemulsion, or a product of the quantum dot synthesis approach described here. Example carrier gases include hydrogen, nitrogen, helium, and argon. For instance, H₂S gas can be diluted in H₂ to a concentration of 1% H₂S and 99% H₂. In some examples, the group VI element-containing compound can be an aqueous solution, such as a water solution of sodium sulfide (Na₂S). In some examples, the group VI element-containing compound can be a solid powder, such as pure anhydrous sodium sulfide (Na₂S) or iron sulfide (FeS)

The synthesis process can be performed at a temperature of, e.g., between about 5° C. and about 50° C., e.g., about 5° C., about 10° C., about 15° C., about 20° C., about 25° C., about 30° C., about 35° C., about 40° C., about 45° C., or about 50° C. The process can be performed at a pressure of, e.g., between about 1 and 5 atmospheres (atm) of pressure, e.g., about 1 atm, about 2 atm, about 3 atm, about 4 atm, or 5 atm. The flow rate of pure inert gas flow rate can range from about 5 milliliter per minute (mL/min) to about 120 mL/min, e.g., about 5 mL/min, about 10 mL/min, about 20 mL/min, about 30 mL/min, about 40 mL/min, about 50 mL/min, about 60 mL/min, about 70 mL/min, about 80 mL/min, about 90 mL/min, about 100 mL/min, about 110 mL/min, or about 120 mL/min. The flow rate of the diluted gas containing Group VI element compound can depend on the reactor size. For instance, for reactors with size between about 20 mL and about 500 mL, the flow rate can be between about 5 mL/min and about 40 mL/min, e.g., about 5 mL/min, about 10 mL/min, about 15 mL/min, about 20 mL/min, about 25 mL/min, about 30 mL/min, about 35 mL/min, or about 40 mL/min. For reactors with size bigger than about 500 mL, the flow rate can be between about 20 mL/min and about 100 m/min, e.g., about 20 mL/min, about 30 mL/min, about 40 mL/min, about 50 m/min, about 60 mL/min, about 70 mL/min, about 80 mL/min, about 90 mL/min, or about 100 mL/min. Other values for temperature, pressure, and flow rate can also be used to maintain the microemulsion template in a stable condition.

When the Group VI element-containing compound is bubbled into the emulsion (216), ions of the group VI element (e.g., S²⁻ ions, in the example of FIG. 2) diffuse into the droplets 212 (218) and react with the Groups I and III metal ions, nucleating nanocrystal clusters 220 (e.g., CuInS₂ nanocrystals, in the example of FIG. 2) in the droplets 212. The clusters 220 grow larger, forming nuclei that coalesce with one another to form nanoparticles 222, e.g., cores for the I-III-VI quantum dots. Because there are no surface ligands in the droplets 212, a single nanoparticle (e.g., core) is formed in each droplet 212. The cores 222 can have a diameter of between about 1 nm and about 25 nm, e.g., about 1 nm, about 2 nm, about 5 nm, about 8 nm, about 10 nm, about 12 nm, about 15 nm, about 18 nm, about 20 nm, about 22 nm, or about 25 nm. The cores 222 can have a narrow size distribution. For instance, the full width at half maximum (FWHM) of emission spectrum of the cores 222 is ≤100 nm, indicating a narrow size distribution because of the correlation between nanoparticle size and peak emission wavelength.

The size of the cores 222 depends on the initial concentration of the Groups I and III metal precursor reactants in the polar (e.g., aqueous solution), but does not depend on reaction time. The composition of the cores 222 depends on the ratio of the Group I metal precursor reactant to the Group III metal precursor reactant in the polar solution. Both the concentration and the ratio can be controlled precisely, enabling precise control over the size and size distribution of the cores 222 that are synthesized in this microemulsion template approach. The size distribution of the cores 222 depends on the size distribution of the droplets 212, which is a thermodynamically controlled process that can be controlled to deliver high size uniformity (e.g., narrow size distribution).

Further description of microemulsion template approaches to nanoparticle synthesis can be found in U.S. Patent Application Publication No. 2005/0006800 and U.S. Pat. No. 7,608,237, the contents of both of which are incorporated here by reference in their entirety.

In some examples, a thin shell of a high band gap material (e.g., ZnS or ZnSe) is grown on the surface of the cores 222 while the cores are still contained in the interior of the droplets 212. For instance, one or more precursor compounds can be provided into the emulsion under conditions suitable for the precursor compounds or ions thereof to diffuse into the interior of the droplets 212. The precursors are a material that can form a semiconductor with a higher band gap than the band gap energy of the cores 222. In some examples, S or Se is provided by bubbling a hydride gas (e.g., H₂S or H₂Se) into the emulsion. In some examples, a liquid solution, e.g., a solution of Na₂S, Thiourea, or Selenourea is mixed into the emulsion. An aqueous solution containing zinc salt (e.g., Zinc acetate, Zinc sulfate, Zinc chloride, Zinc nitrate) can be used as Zn²⁺ precursor to react with S or Se precursor to form the shell. The concentration and volume of the precursor compounds can affect the stability and thickness of the shell. Due to the limitation of volume of polar solvent to form stable spherical emulsion droplets, a high concentration of Zn²⁺ and S²⁻ or Se²⁻ precursor can be used, e.g., a concentration of 1M or 2M or a concentration that approaches or reaches a maximum solubility limit. In some examples, a solid, such as a solid powder, e.g., pure anhydrous of Na₂S, Thiourea, or Selenourea solid chemical, is mixed directly with the emulsion. The solid chemical slowly dissolves in the polar phase of the microemulsion and decomposes and hydrolyses to form precursor ions. A solid chemical containing zinc salt (e.g., Zinc acetate, Zinc sulfate, Zinc chloride, Zinc nitrate) can also be used as Zn²⁺ precursor to be dissolved into microemulsion droplets to react with S²⁻ or Se²⁻ precursor to form the shell. Using solid powder of salts as a precursor takes a longer time to grow the shell. If both shell precursors are provided as solid powder, the second precursor is not added until all of the first precursor solid is completely dissolved into the microemulsion droplets. Coating core dots with a thin shell inside microemulsion template can be performed at a temperature that does not affect the stability of the microemulsion template, e.g., a temperature between about 5° C. and about 50° C., e.g., about 5° C., about 10° C., about 15° C., about 20° C., about 25° C., about 30° C., about 35° C., about 40° C., about 45° C., or about 50° C. In some examples, a specific volume of Na₂S aqueous solution is mixed with specific volume of microemulsion which contains specific size of core dots and is allowed to react at room temperature with magnetic stirring for, e.g., 4-24 hours, following by adding an equal molar amount of Zn²⁺ precursor aqueous solution to react with the S²⁻ precursor. The whole mixture is continuously stirred for, e.g., 24 hours or sonicate for, e.g., 30-60 minutes to complete the reaction. In some examples, especially for the synthesis of core nanoparticles with excess amount of the Group VI element, adding only the Zn²⁺ precursor can be sufficient to grow a thin ZnS shell. The Zn²⁺ precursor can be provided as an aqueous solution or as a solid powder. A specific volume of Zn²⁺ precursor aqueous solution or precursor salt powder is mixed with a microemulsion which contains a specific size of core quantum dots and is allowed to react at room temperature with magnetic stirring for, e.g., at least 24 hours to complete the shell growing reaction. The amount of ZnS or ZnSe precursor to be added can be estimated by knowing the thickness of shell expected and the size of core dots. The thickness of the thin shell formed on the core dots in the microemulsion template approach can be between, e.g., about 0.3 nm and about 1 nm. The resulting structure, formed of an I-II-VI semiconductor core capped with a thin shell of a high band gap material, is referred to as a thin-shell quantum dot.

The thin-shell quantum dots are functionalized with ligands, such as hydrophobic or hydrophilic ligands. Functionalization with hydrophilic ligands can occur while the thin-shell quantum dots are still contained in the interior of the droplets 212. Functionalization with hydrophobic ligands can occurs when the droplets 212 are broken. This functionalization helps with extraction of the thin-shell quantum dots from the emulsion. The thin-shell quantum dots typically have surface defects and weak emission. Upon extraction, the thin-shell quantum dots are annealed and a thicker shell is grown thereon, thereby improving the quantum yield and stability of the quantum dots and producing core-shell quantum dots soluble in water or organic solvents. In some examples, core-shell quantum dots soluble in organic solvents (e.g., functionalized with hydrophobic ligands) are surface modified by ligand exchange to form water soluble core-shell quantum dots, e.g., quantum dots with functional groups capable of bio-conjugation.

Examples of hydrophilic surface ligands for functionalization of the thin-shell quantum dots in the microemulsion can be thiol-carboxylic acid or thiol-hydroxyls (e.g., mercaptosuccinic acid, 3-mercaptopropionic acid, thiol-(PEG)ₙ-carboxylic acid, thiol-(PEG)ₙ-hydroxyl, mercaptoundecanoic acid, mercapohexadecanoic acid, mercaptopropanol, mercaptohexanol, or other suitable ligands). In a specific example, the surface functionalization and extraction process can be performed as follows for functionalization with hydrophilic ligands: a specific amount of pure thiol-carboxylic acid is added into a specific volume of microemulsion which contains thin-shell quantum dots and mixed with magnetic stirring for, e.g., a minimum of 24 hours at room temperature. An at least equal volume of a solvent, such as methanol or ethanol, is mixed with this microemulsion mixture to break down the microemulsion, followed by adding a basic chemical solution (e.g., 1M sodium hydroxide water solution, 1M tetramethylammonium hydroxide water solution, 1M potassium tert-butoxide methanol solution, or another suitable basic solution) to deprotonate the carboxylic acid group. The amount of thiol-carboxylic acid and basic chemical added depends on the volume of microemulsion treated. As an example, to treat 5 mL of microemulsion which contains thin-shell quantum dots, 5-30 mg of mercaptopropionic acid is added to functionalize the surface of the quantum dots, and 50-400 μl of 1M NaOH solution is added to deprotonate the carboxylic acid. A strong non-polar solvent (e.g., diethyl ether) is added into the methanol-microemulsion mixture which contains the hydrophilic thin-shell quantum dots to help precipitate the hydrophilic dots. The volume of non-polar solvent added in is, e.g., at least 20% more than that the volume of the methanol-microemulsion mixture (e.g., for 10 mL of methanol-microemulsion mixture, at least 12 ml of diethyl ether is added). Centrifugation can be performed to accelerate the precipitation process. The liquid phase chemicals are discarded after centrifugation, and the solid hydrophilic quantum dots are dispersed in a polar solvent, e.g., water, for further annealing and shell growth process.

Examples of hydrophobic surface ligands include, e.g., fatty acids, such as lauric acid, oleic acid, or other suitable fatty acids; alkanamines, such as hexadecylamine, oleic amine, dodecylamine, or other suitable alkanamines; phosphines, such as trioctylphosphine, tributyl phosphine, trioctylphosphine oxide, or other suitable phosphines; or alkanethiols, such as 1-dodecanethiol or other suitable alkanethiols; or other suitable hydrophobic ligands, or mixtures thereof. In a specific example, the surface functionalization and extraction process can be performed as follows for functionalization with hydrophobic ligands: a specific amount of hexadecylamine is dissolved in methanol. The methanol-hexadecylamine solution is added into a specific volume of microemulsion which contains thin-shell quantum dots and mixed with magnetic stirring for, e.g., a minimum of 2 hours at room temperature to break down the microemulsion and passivate the thin-shell quantum dots with hydrophobic surface ligands. The amount of hydrophobic ligand and the volume of methanol is estimated based on the volume of microemulsion processed. As an example, to treat 5 mL of microemulsion which contains thin-shell quantum dots, 0.1-0.5 g of hexadecylamine is added to passivate the quantum dots surface, and 5-10 mL of methanol is added to break down the microemulsion. The hydrophobic ligand passivated thin shell quantum dots will precipitate out of the methanol-P-xylene-P105 mixture. Centrifugation can be performed to accelerate the precipitation process. The liquid phase chemicals are discarded after centrifuge, and solid hydrophobic quantum dots are dispersed in an organic solvent, such as hexane, heptane or methanol for further annealing and shell process performed. For instance, hydrophobic thin-shell quantum dots can be annealed and shelled in a batch reactor at high reaction temperature.

In the example of FIG. 2, the precursor reactants are dissolved in the polar solvent such that the droplets of the polar solvent are dispersed in the non-polar solvent and encapsulated by the interfacially active material. In some examples, the precursor reactants can be dissolved in the non-polar solvent such that droplets of the non-polar solvent are dispersed in the polar solvent and encapsulated by the interfacially active material.

In the example of FIG. 2, the microemulsion template assisted approach produces nanoparticle quantum dot cores. The shape of the template droplets, and hence the shape of the nanostructures produced by this microemulsion template assisted approach, can be varied by varying the relative amounts of the polar solvent, the non-polar solvent, and the interfacially active material. Template shapes can be spherical microemulsion droplets, liquid crystals of hexagonally packed arrays of cylinders, liquid crystals of laminar phases, bicontinuous phases, or other shapes.

FIG. 3 is a diagram of a gas-liquid contacting reactor 300 for batch synthesis of I-III-VI semiconductor quantum dot cores using a microemulsion template based synthesis process. The reactor 300 can be used to produce large quantities of I-III-VI semiconductor quantum dot cores. A solution of the precursor reactants containing Group I and III metals in specific concentrations in a solvent, e.g., a polar solvent, is mixed with a non-polar solvent and an interfacially active material to form a stable microemulsion. In an example, the precursor reactants are Cu¹⁺ and In³⁺ in water, with specific concentrations and a specific Cu¹⁺/In³⁺ ratio; the non-polar solvent is p-xylene; and the interfacially active material is the surfactant Pluronic P105, resulting in microemulsion template droplets having a size of between about 30 nm and about 40 nm. The microemulsion is transferred into a glass reactor 302 that is connected to a fluid (e.g., gas) flow network 304. An inert gas, such as nitrogen, is provided from a gas source 306 and bubbled into the reactor 302 to degas the microemulsion.

The gaseous Group VI element-containing compound diluted in a carrier gas (e.g., H₂S diluted in H₂) is provided from a gas source 308 and bubbled into the reactor 302. The flow rate of the gas from the gas source 308 is controlled by a flow controller 310 including one or more valves and flow meter. The gaseous Group VI element-containing compound diffuses into the microemulsion droplets, reacting with the precursor reactants to form I-III-VI semiconductor quantum dot cores (e.g., nanocrystals of CuInS₂) in the microemulsion template droplets. Excess of the gaseous Group VI element-containing compound that did not diffuse into the microemulsion droplets or was not absorbed by microemulsion template is burned off at a cracking furnace 312.

The synthesis process can be performed at a temperature of, e.g., between about 5° C. and about 50° C., e.g., about 5° C., about 10° C., about 15° C., about 20° C., about 25° C., about 30° C., about 35° C., about 40° C., about 45° C., or about 50° C. The process can be performed at a pressure of, e.g., between about 1 and 5 atmospheres (atm) of pressure, e.g., about 1 atm, about 2 atm, about 3 atm, about 4 atm, or 5 atm. The flow rate of pure inert gas flow rate can range from about 5 milliliter per minute (mL/min) to about 120 mL/min, e.g., about 5 mL/min, about 10 mL/min, about 20 mL/min, about 30 mL/min, about 40 mL/min, about 50 mL/min, about 60 mL/min, about 70 mL/min, about 80 mL/min, about 90 mL/min, about 100 mL/min, about 110 mL/min, or about 120 mL/min. The flow rate of the diluted gas containing Group VI element compound can depend on the reactor size. For instance, for reactors with size between about 20 mL and about 500 mL, the flow rate can be between about 5 mL/min and about 40 mL/min, e.g., about 5 mL/min, about 10 mL/min, about 15 mL/min, about 20 mL/min, about 25 mL/min, about 30 mL/min, about 35 mL/min, or about 40 mL/min. For reactors with size bigger than about 500 mL, e.g., between 500 mL and 10 L, the flow rate can be between about 20 mL/min and about 100 mL/min, e.g., about 20 mL/min, about 30 mL/min, about 40 mL/min, about 50 mL/min, about 60 mL/min, about 70 mL/min, about 80 mL/min, about 90 mL/min, or about 100 mL/min. Other values for temperature, pressure, and flow rate can also be used to maintain the microemulsion template in a stable condition.

The reaction time depends on the flow rate of diluted gas containing Group VI element compound, the precursor concentration and the size of reactor. In general, the flow rate is selected such that the reaction time is not too short to be controlled. As an example, for a 100 mL reactor which contains microemulsion using 0.3 M precursor concentration, and 20 mL/min flow rate, the reaction is completed in about 10-12 minutes.

The size and crystal structure of the quantum dots is affected by factors including concentration of the precursor reactants in the polar solvent, the ratio of Group I metal precursor reactant to the group III precursor reactant, the flow rate and flow time of the gaseous Group VI element-containing compound, and the relative concentrations of the polar solvent, the non-polar solvent, and the interfacially active material.

Following synthesis of the quantum dot cores, a thin shell of a high band gap material (e.g., ZnS or ZnSe) is grown on the surface of the cores while the cores are still contained in the interior of the droplets. The thin-shell quantum dots are functionalized with hydrophilic surface ligands or hydrophobic ligands to assist with extraction of the quantum dots from the emulsion. The extracted, ligand-functionalized thin-shell quantum dots can be dispersed in an appropriate solvent. For instance, thin-shell quantum dots passivated with hydrophilic surface ligands are dissolved in water. Thin-shell quantum dots passivated with hydrophobic ligands are dissolved in an organic solvent such as hexane, heptane, methanol, chloroform, or another appropriate organic solvent.

The synthesis of thin-shell quantum dots and functionalization of the quantum dots with hydrophilic or hydrophobic surface ligands occurs in a single reactor. The extracted, functionalized thin-shell quantum dots are water soluble or soluble in organic solvents, depending on the nature of the ligands, and can be provided directed to an annealing process (described infra) without purification, further functionalization, or solvent switching. The annealing process can be a continuous flow anneal process or a batch anneal process.

In some examples, the extracted thin-shell quantum dots synthesized using the microemulsion template approach described supra are annealed in a continuous flow, dynamic annealing process. The dynamic annealing process stabilizes the quantum dots and facilitates the removal of defects from the crystalline structure of the quantum dots, thereby increasing their quantum yield. In a dynamic annealing process, the quantum dots are subjected to repeated heating-cooling cycles. In each heating-cooling cycle, the quantum dots are heated to a target heating temperature and then cooled to a target cooling temperature. The heating portion of the heating-cooling cycle promotes surface restructuring of the quantum dots. The cooling portion of the heating-cooling cycle promotes surface relaxation of the quantum dots. This dynamic annealing process helps to prevent secondary degradation of the organic ligands of the quantum dots, which can result in a broadening of the size distribution of the quantum dots. The cycling of the dynamic annealing process to temperatures below the boiling point of most solvents enhances safety and enables the use of a range of solvents, including water, during the annealing process.

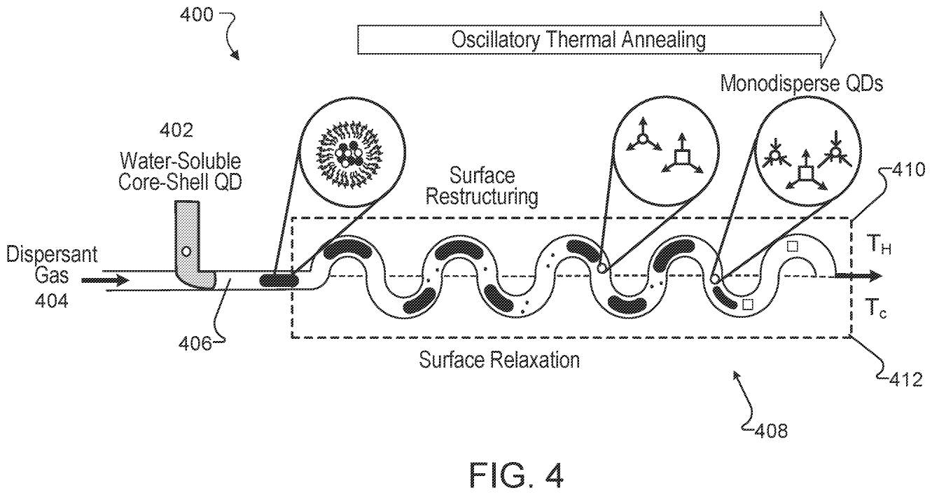

FIG. 4 shows an example microfluidic system 400 for dynamic, rapid thermal annealing of quantum dots, such as quantum dot cores or thin-shell quantum dots. Ligand-functionalized, thin-shell quantum dots soluble in water or organic solvents, depending on the nature of the ligands, are extracted from the microemulsion and a solution 402 (e.g., an aqueous solution or a solution in an organic solvent) of the extracted thin-shell quantum dots enters into a fluid flow along with a dispersant gas 404, such as argon or nitrogen. Droplets of the solution 402 dispersed in the gas 404 flow through a tube 406 of a microreactor 408. The microreactor 408 has a dual jacketing system in which a heating fluid is applied to one half 410 of the loop of the microreactor 408 and a cooling fluid, e.g., water, is applied to another half 412 of the loop of the microreactor 408. The dual jacketing system results in a microdroplet experiencing temperature oscillations of successive heating-cooling cycles as it flows along the axial direction of the tube 406. A back pressure regulator (not shown) is employed to maintain the aqueous solution of the NIR QDs in a liquid state even during the heating portions of the heating-cooling cycles. The number of heating-cooling cycles and the frequency of the temperature oscillations (e.g., the residence time of the fluid in each portion of the dual jacketing system) are controlled by the bend radius of the tube 406, the flow rate of the fluid through the tube 406, and the length of the tube 406.

The frequency of the heating-cooling cycles of the dynamic annealing process is between about 0.0001 Hz and about 1 Hz, e.g., about 0.0001 Hz, about 0.001 Hz, about 0.01 Hz, about 0.1 Hz, about 0.5 Hz, or about 1 Hz. The dynamic annealing process includes at least 10 heating-cooling cycles, e.g., between 10 and 1000 heating-cooling cycles, e.g., 10, 50, 100, 500, or 1000 heating-cooling cycles. During the heating portion of the heating-cooling cycle, the NIR QDs are heated to a temperature of between about 200° C. and about 250° C., e.g., about 200° C., about 225° C., or about 250° C. During the cooling portion of the heating-cooling cycle, the NIR QDs are cooled to a temperature of between about 10° C. and about 40° C., e.g., about 10° C., about 15° C., about 20° C., about 25° C., about 30° C., about 35° C., or about 40° C. The temperatures in the heating and cooling portions are selected such that the heating temperature does not evaporate the ligands, and the low temperature keeps the solution of quantum dots as a flowable liquid.

In some examples, the emission spectra of the NIR QDs are testing inline along the tube 406 to determine quantum yield. For instance, the dynamic annealing processing following microemulsion template synthesis of NIR QDs results in a quantum yield of greater than about 40% in an aqueous medium. Other characterization of the NIR QDs, e.g., characterization of particle size, surface morphology, or other appropriate characterizations, can be performed ex situ following completion of the dynamic annealing process.

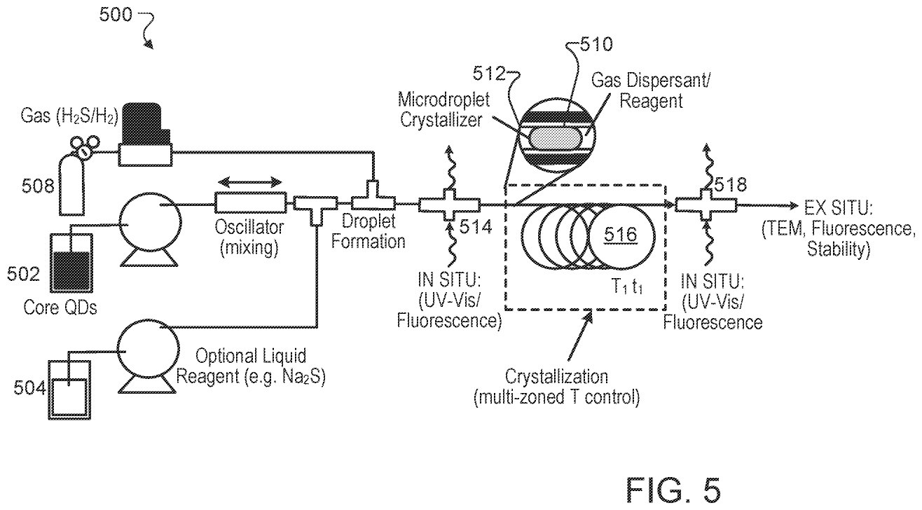

FIG. 5 is a schematic diagram of a segmented flow microreactor 500 for growth of thick shells on the annealed, thin-shell quantum dots described supra and for functionalization of the core-shell quantum dots with surface ligands. Functionalized thin-shell quantum dots 502 (e.g., functionalized with hydrophilic or hydrophobic ligands) are mixed with a precursor of the shell composition 504 to form a mixture. The precursor can be a Zn²⁺ precursor solution, e.g., Zn(Ac)₂, ZnCl₂, or ZnSO₄ in water. The mixture is dispersed into a dispersant gas 508, such as argon or H₂S, resulting in formation of droplets 510 of the mixture in a gas phase 512. The thin-shell quantum dots in the droplets 510 can be characterized in situ at a characterization station 514 implementing, e.g., ultraviolet-visible spectroscopy (UV-vis) or fluorescence spectroscopy. For instance, the size, optical properties, stability, or other characteristics of the quantum dots can be characterized. When the dispersant gas 508 is H₂S, the dispersant gas 508 also acts as a reagent for the shell (e.g., for a ZnS shell) by equilibrating with the droplets 510 to provide a source of sulfur.

The droplets 510 pass through a tubular coiled reactor 516 at sufficient velocity to achieve desired residence times in the reactor 516. The residence times can be between about 1 minute and about 300 minutes, e.g., about 1 minute, about 5 minutes, about 10 minutes, about 15 minutes, about 30 minutes, about 60 minutes, about 90 minutes, about 120 minutes, about 150 minutes, about 180 minutes, about 210 minutes, about 240 minutes, about 270 minutes, or about 300 minutes. The output of the reactor 516 is water soluble quantum dots having a thick shell of a high band gap material, e.g., ZnS or ZnSe, and exhibiting fluorescence emission in a target wavelength range, with narrow FWHM and high brightness. A second characterization station 518 implementing, e.g., UV-vis or fluorescence spectroscopy, characterizes the quantum dots output from the reactor 516. For instance, the size, optical properties, stability, or other characteristics of the quantum dots can be characterized.

The flow rate of the thin-shell quantum dots 502 and the precursor 504 are controlled by flow controllers, e.g., syringe pumps, valves, or other appropriate flow controllers. The temperature of elements of the system is controlled by temperature controllers, e.g., thermal reservoirs such as oil baths. The flow of the dispersant gas 508 is blended and maintained using gas flow controllers, e.g., thermal mass flow controllers.

The thin-shell quantum dots 502 and the precursor 504 can be flowed at flow rates of between about 0.01-5 mL/min, e.g., about 0.01 mL/min, about 0.05 mL/min, about 0.1 mL/min, about 0.5 mL/min, about 1 mL/min, about 2 mL/min, about 3 mL/min, about 4 mL/min, or about 5 mL/min. The dispersant gas 508 can be flowed at a flow rate of between about 0 and about 200 sccm, e.g., about 0 sccm, about 1 sccm, about 5 sccm, about 10 sccm, about 25 sccm, about 50 sccm, about 100 sccm, about 150 sccm, or about 200 sccm. Elements of the system can be maintained at a temperature of between about 20° C. and about 200° C., e.g., about 20° C., about 50° C., about 75° C., about 100° C., about 125° C., about 150° C., about 175° C., or about 200° C.

In some examples, to improve the quantum yield and remove surface defects of thin-shell quantum dots, such as hydrophobic thin-shell quantum dots, the annealing and shelling processes are performed in a high temperature batch reactor system. Hydrophobic thin-shell quantum dots dispersed in an organic solvent such as hexane, heptane, methanol, or other appropriate organic solvent are transferred into a batch reactor which contains hydrophobic surface ligands as high temperature coordinating solvents. The coordinating solvents can be, e.g., fatty acids, such as lauric acid, oleic acid, or other suitable fatty acids; alkanamines, such as hexadecylamine, oleic amine, dodecylamine, or other suitable alkanamine; phosphines, such as trioctylphosphine, tributyl phosphine, trioctylphosphine oxide, or other suitable phosphines; or alkanethiols, such as 1-dodecanethiol or other suitable alkanethiols; or other suitable hydrophobic ligands, or mixtures thereof. The coordinating solvent can be only one type of hydrophobic surface ligands or a mixture of several different types of surface ligands with specific ratio. The hydrophobic thin-shell quantum dots with coordinating solvents are heated in a batch reactor under an inert atmosphere (e.g., N₂ or Argon) to a high temperature, e.g., between about 200° C. and about 300° C. and kept for, e.g., between about 1 hour and about 3 hours. The temperature is then reduced to a lower temperature, e.g., between about 60° C. and about 100° C., and the reaction mixture is maintained at this lower temperature for another, e.g., 2-4 hours to complete the annealing process. To coat hydrophobic thin-shell quantum dots with a thicker shell, a mixture of precursors of the shell composition are injected into the batch reactor, e.g., as droplets, resulting in the formation of core-shell structures. The precursors can be, e.g., a mixture of precursors to ZnS in trioctylphosphine or tributylphosphine. The sulfur precursor can be, e.g., hexamethyl(disilathiane)(TMS₂S) and the zinc precursor can be, e.g., diethylzinc or dimethylzinc, zinc acetate, zinc stearate, or zinc acetylacetonate, or other suitable zinc precursor. If an alkanethiol is used as the coordinating solvent, the coordinating solvent can also function as sulfur precursor. The shelling temperature or the shell precursor injection temperature can be between, e.g., about 130° C. and about 220° C. The precursor injection temperature is determined based on the size of the core dots, with a higher injection temperature used for larger size cores and relatively lower injection temperature used for smaller core sizes. After completion of shell precursor solution injection, the reaction mixture is kept at precursor injection temperature for, e.g., 0.5-2 hours to form a semiconductor shell with a crystalline structure. The reactor temperature is subsequently reduced to, e.g., between about 60° C. and about 100° C. and kept for several hours to complete the annealing and shelling process, resulting in NIR core shell quantum dots with high quantum yield.

In some examples, following the annealing and shelling process, hydrophobic NIR core-shell quantum dots are converted into water soluble NIR core-shell quantum dots by ligand exchanging with hydrophilic surface ligands, such as thiol-carboxylic acid and thiol-hydroxyl, i.e. mercaptopropionic acid, mercaptoundecanoic acid, mercaptohexadecanoic acid, thiol-(PEG)ₙ-carboxylic acid, thiol-(PEG)ₙ-hydroxyl, mercaptopropanol and mercaptohexanol, The hydrophilic surface ligands used for ligand exchange can all have the same functional group, or a combination of different functional groups can be used, e.g., to produce quantum dots functionalized with both —COOH and —OH functional groups.

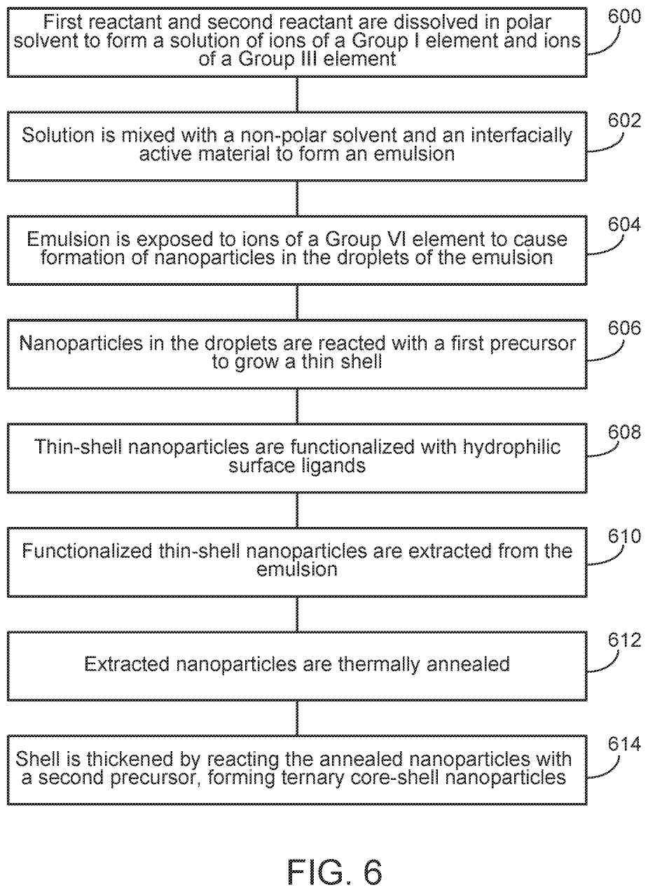

FIG. 6 is a flow chart of an example process for synthesizing cadmium-free near-infrared core-shell quantum dots based on I-III-VI ternary semiconductors. In the process of FIG. 6, the nucleation and growth of the cores is separated from the annealing and shelling processes.

A first reactant and a second reactant are dissolved in polar solvent to form a solution of ions of a Group I element (e.g., ions of Cu or Ag) and ions of a Group III element (e.g., ions of In or Ga) (600). The first reactant includes a Group I element-containing compound, such as a salt of the Group I element, e.g., CuI, CuCl, or AgNO₃. The second reactant includes a Group III element-containing compound, such as Indium (III) acetate or Indium (III) sulfate. The polar solvent is water or formamide.

In some examples, dissolving the first and second reactants in the polar solvent includes adjusting the pH of the polar solvent, e.g., by adding an acid or a base to the polar solvent, to promote dissolution of the first and second reactants. In some examples, the first reactant is dissolved in a basic solution of the polar solvent and the second reactant is dissolved in an acidic solution of the polar solvent, and the two solutions are combined to form the solution of the ions of a Group I element and the ions of a Group III element.

The solution of the ions of the Group I element and ions of the Group III element in the polar solvent is mixed with a non-polar solvent and an interfacially active material to form an emulsion (602). The emulsion includes droplets of the solution of the ions of the Group I element and ions of the Group III element in the polar solvent dispersed in a continuous phase of the non-polar solvent. The droplets are encapsulated by an interfacially active material. The non-polar solvent includes an alkane or an alkene. The interfacially active material includes an amphiphilic block copolymer, a surfactant, a water-dispersible polymer, an amphiphilic molecule, a solid particle, or a solvent-swollen particle.

The emulsion is exposed to ions of a Group VI element, such as S, Se, or Te, under conditions sufficient to permit the ions of a Group VI element to react with the ions of the Group I element and ions of the Group III element in the droplets to form nanoparticles in the droplets (604). The emulsion can be exposed to the ions of the Group VI element by contacting the emulsion with a gas containing a Group VI element-containing compound, such as a hydride of the Group VI element, e.g., by bubbling the gas into the emulsion.

The nanoparticles have a composition ABX_{y}, where A is the Group I element, B is the Group III element, and X is the Group VI element. For instance, the nanoparticles can be CuInS₂, CuInSe₂, AgInS₂, or AgInSe₂ nanoparticles.

By introducing zinc and sulfur or selenium precursors into the microemulsion droplets, the two precursors can react and grow a thin shell around the core of nanoparticles, thereby forming thin-shell core-shell nanoparticles (606) in the microemulsion droplets. The thin shell can be ZnS or ZnSe; the zinc precursor can be, e.g., zinc acetate, zinc sulfate, zinc chloride, or another appropriate zinc precursor; the sulfur precursor can be, e.g., sodium sulfide, thiourea, hydrogen sulfide gas, or another suitable sulfur precursor; and the selenium precursor can be, e.g., selenourea, hydrogen selenide, or another appropriate selenium precursor.

The thin-shell core-shell nanoparticles are passivated with hydrophilic or hydrophobic surface ligands (608), depending on the desired solubility for the nanoparticles, and extracted from the emulsion (610).

The extracted thin-shell core-shell nanoparticles are thermally annealed (612). In some examples, the annealing is a continuous flow anneal process in which the nanoparticles are exposed to multiple cycles of heating and cooling. Thermally annealing the nanoparticles can include flowing a solution of the nanoparticles (e.g., an aqueous solution of hydrophilic nanoparticles) through a flow channel and applying heating fluid and cooling fluid to alternating portions of the flow channel to expose the nanoparticles to the multiple cycles of heating and cooling. The multiple cycles of heating and cooling can be an alternation between heating the nanoparticles to a temperature of between 200° C. and 250° C. and cooling the nanoparticles to a temperature of between 10° C. and 40° C., e.g., with a frequency of between 0.0001 Hz and 1 Hz. In some examples, the annealing is a batch anneal process in which the thin-shell core-shell nanoparticles (e.g., a solution of hydrophobic nanoparticles in an organic solvent) are heated to a high temperature in a batch reactor.

The annealed nanoparticles are reacted with a second precursor to thicken the shell on the nanoparticles, thereby forming ternary core-shell nanoparticles (614). The shell can have the same composition as the thin shell, e.g., ZnS or ZnSe, and the second precursor can be a precursor to the ZnS or ZnSe composition. The shell growth process can be a continuous flow process or a batch process.

The resulting ternary core-shell nanoparticles have a fluorescence emission wavelength of between 650 nm and 840 nm, a fluorescence emission spectrum with a full width at half maximum of less than 100 nm, and a quantum yield of at least 40% in aqueous solution.

### Example 1—Synthesis of CuInS₂ Quantum Dots

CuInS₂ quantum dot cores were synthesized according to the microemulsion template approach described supra. To synthesize this composition, sufficient Cu¹⁺ and In³⁺ ions were dissolved in water starting from precursors including CuI or CuCl and Indium (III) acetate or Indium (III) sulfate, respectively. To enhance the solubility of these precursors, both the Cu¹⁻ and the In³⁺ precursors were dissolved in a diluted ammonium hydroxide solution (2N) or hydrochloric acid (HCl) solution (3N) to reach the desired precursors concentration. These acid solution or base solution or neutral inorganic salts water solution were used as the polar phase to prepare the microemulsion templates. CuInS₂ quantum dot cores then were synthesized by introducing sulfur precursor into the microemulsion droplets. The sulfur precursor sources can be sodium sulfide (Na₂S) water solution, solid Na₂S powder or hydrogen sulfide (H₂S) gas.

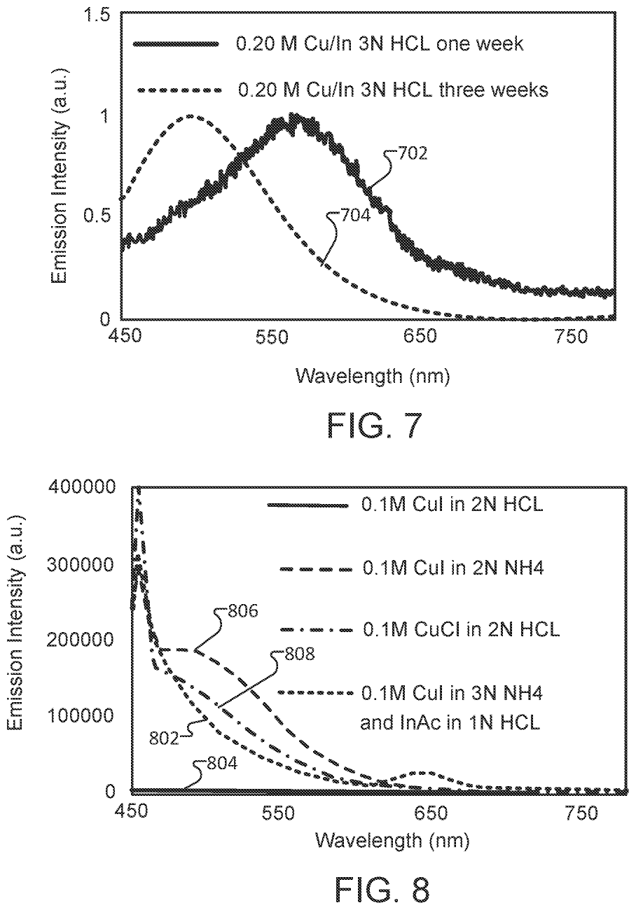

FIG. 7 shows the emission intensity spectra for CuInS₂ quantum dot cores one week (702) and three weeks (704) after preparation by using CuCl as Cu¹⁺ precursor source, In(Ac)₃ as In³⁺ precursor source and 2M Na₂S water solution as S²⁻ precursor source. Both Cu¹⁺ precursor and In³⁺ precursor salts were dissolved in 3N HCl solution. These spectra demonstrate that while the as-prepared quantum dot cores shows fair fluorescence emission intensity, they were unstable and exhibited a blue shift with storage in a strong acid solution.

A second synthesis experiment was performed by dissolving a Cu¹⁺ precursor (CuI) in a 3N NH₄ basic solution and an In³⁺ precursor (In(Ac)₃) in a 1N HCl acid solution. The two solutions were mixed together and quantum dots were synthesized according to the microemulsion template approach. FIG. 8 shows the emission intensity spectra (802) for these quantum dots. These quantum dot cores, which were synthesized using a 3N basic solution and a 1N acidic solution, exhibited improved fluorescence emission intensity and exhibited a red shift compared to the quantum dots of FIG. 7, which were synthesized using a 3N acidic solution.

The effect of different Cu¹⁺ precursors was also studied. Quantum dot cores were synthesized using the microemulsion template approach described here, by dissolving both CuI and Indium (III) acetate in a 2 N HCl solution (spectrum 804) to a concentration of 0.1 M, both CuI and Indium (III) acetate in a 2 N NH4 solution spectrum (806) to a concentration of 0.1 M, and both CuCl and Indium (III) acetate in a 2 N HCl solution (spectrum 808) to a concentration of 0.1 M. As can be seen from the various spectra, the solubility of the precursor in aqueous solution affects the optical properties of the resulting quantum dot cores.

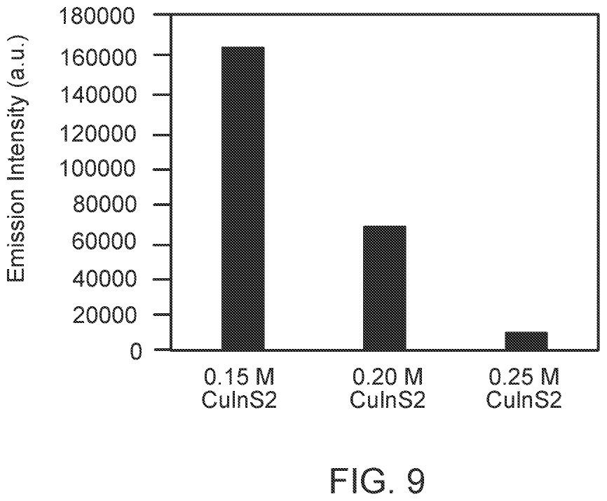

FIG. 9 shows the emission intensity for CuInS₂ quantum dot cores synthesized using the microemulsion template approach described here, with different precursor concentrations. Lower precursor concentration results in smaller diameter quantum dot cores, which showed much stronger fluorescence intensity compared with quantum dot cores synthesized with higher precursor concentrations.

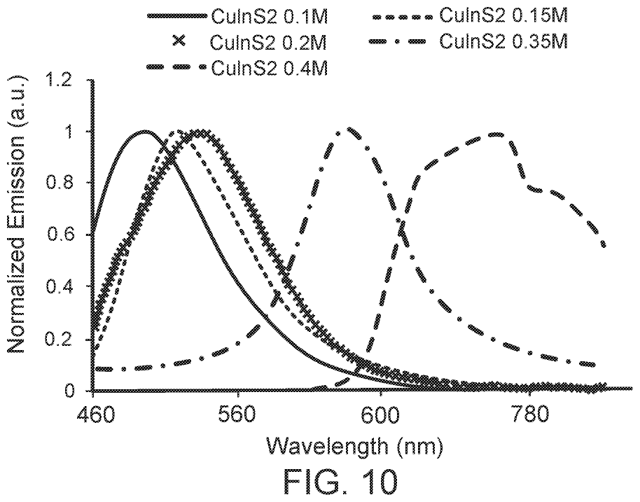

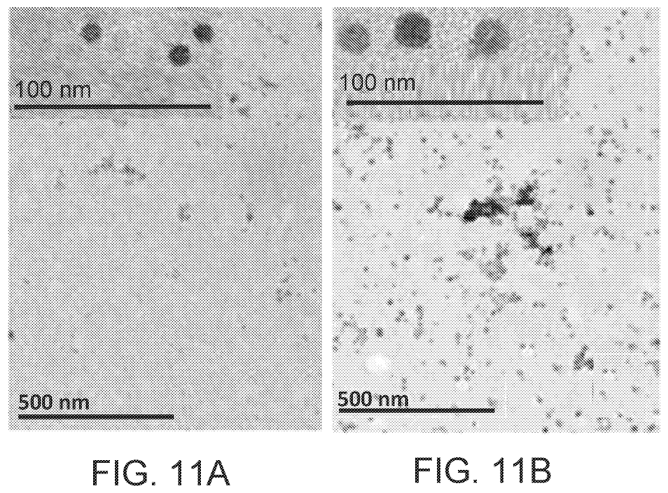

FIG. 10 shows the normalized emission spectra for CuInS₂ quantum dot cores synthesized using the microemulsion template approach described here and with sulfur deficiency, with precursor concentrations of 0.1 M through 0.4 M. CuI and Indium (III) acetate in a 1.5 N HCl solution were used as Cu¹⁺ and In³⁺ precursor sources and 2M Na₂S deionized (DI) water solution was used for the S²⁻ precursor source. As the precursor concentration increases and the size of the quantum dot cores increases, the emission spectra of the quantum dots undergo a red shift. For CuInS₂ nanoparticles synthesis using CuI and In(Ac)₃ in HCl solution and Na₂S in water solution as precursors, the polar phase of the microemulsion is strong acidic condition, such that a portion of the S²⁻ has the ability to release from the surface of the nanoparticle crystals and exist as hydrogen sulfide gas. As a result, CuInS₂ nanoparticle synthesis with this combination of precursors exhibited large blue shift with storage time extended due to deficiency of S²⁻ ions. Referring to FIG. 11, transmission electron microscopy images of the core quantum dots with the emission spectra shown in FIG. 10 confirm that the quantum dot cores synthesized with higher precursor concentration (FIG. 11B) are larger than those synthesized with smaller precursor concentration (FIG. 11A).

In addition to different Cu¹⁺ precursor sources, CuInS₂ nanoparticle synthesis experiments were also performed using different In³⁺ precursor sources, including In₂(SO₄)₃, and different S²⁻ precursor sources, such as H₂S gas, and following the microemulsion template approach described here. An example group of CuInS₂ nanoparticles with different molar precursor concentrations from 0.15M to 0.5M were synthesized according to the following processes using various precursors different from those addressed in the foregoing examples.

Cu¹⁺ precursor bulk solution was prepared by dissolving an appropriate amount of CuI salt in 2N NH4-OH water solution to reach 1M concentration. In³⁺ precursor bulk solution was prepared by dissolving an appropriate amount of In₂(SO₄)₃ in DI water to reach 1M concentration. Then 0.15M, 0.2M, 0.25M, 0.3M, 0.35M, 0.4M, 0.45M, and 0.5M Cu¹⁺ and In³⁺ solutions with a Cu¹⁺/In¹⁺ molar ratio 1:1 were prepared by mixing an appropriate volume of each precursor bulk solution and diluting with DI water. The precursor water solution was subsequently mixed with P-xylene and Pluronic® P105 and stirred overnight to form stable microemulsion templates. Hydrogen sulfide gas was introduced into a glass bottle reactor which contained the stable microemulsion template in order to be absorbed by the microemulsion and then react with Cu¹⁺ and In³⁺ ions to form CuInS₂ nanoclusters inside each microemulsion droplet. The hydrogen sulfide gas was produced by a house-made gas reactor. The glass bottle containing microemulsion templates with Cu¹⁻ and In³⁺ ions was put into a secondary container which can be sealed without leaking. A small vial which contained an appropriate amount of iron sulfide (FeS) solid powder was also put into the same container. The secondary container was sealed and 5M hydrogen sulfate acid water solution was injected drop-wise, slowly and continuously, into the small vial which contained FeS to allow FeS react with H₂SO₄ to produce H₂S gas. The generated H₂S gas was absorbed by the microemulsion templates and the gas molecules subsequently diffused into the microemulsion droplets to react with Cu¹⁺ and In³⁺ ions. The color of the microemulsion changed from a light yellow-green color into a dark brown color, which indicated the formation of CuInS₂ nanoparticles.

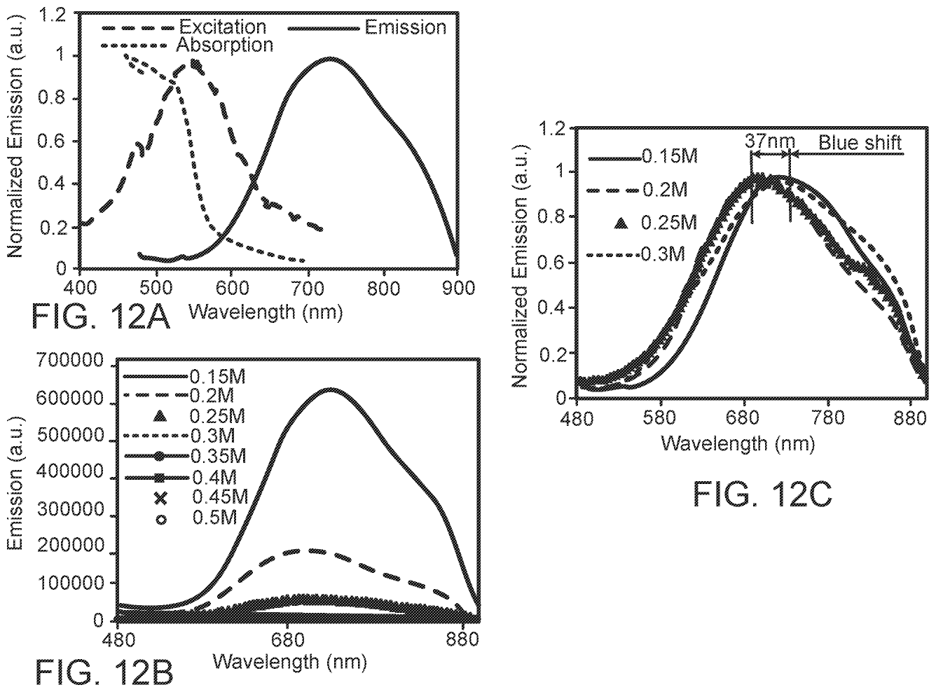

The reaction can be performed for up to 24 hours, but the longer the reaction lasts, more excess of H₂S is absorbed by the microemulsion. A minimum of 4 hours of reaction time is suitable for 40 mL of microemulsion template. For a larger volume of microemulsion, longer H₂S exposure time is appropriate. Nanoparticle synthesis with these combinations of precursors were carried out in S²⁻ ion-rich conditions. The photoluminescence properties of as-prepared CuInS₂ nanoparticles in microemulsion were measured and are illustrated in FIGS. 12A-12C.

FIG. 12A shows normalized absorption, excitation, and emission spectra for CuInS₂ core nanoparticles synthesized with 0.15M CuI/In₂(SO₄)₃ precursor concentration and an excess of sulfur. FIG. 12B shows emission spectra of CuInS₂ core nanoparticles synthesized with different precursor concentrations. From FIG. 12B, it can be observed that the fluorescence emission intensity of core CuInS₂ core nanoparticles shows a negative correlation with precursor concentration. For samples with low precursor concentration, the emission fluorescence intensity is stronger than that of nanoparticles synthesized with higher precursor concentration. The emission intensity of core nanoparticles synthesized with 0.15M precursor concentration is 10 times stronger than that of core nanoparticles synthesized with 0.5M precursor concentration.

Unlike the emission spectra for nanoparticles synthesized under S²⁻ ion deficiency conditions, the peak emission wavelength of CuInS₂ nanoparticles synthesized with H₂S gas saturation condition in microemulsion templates show a negative correlation with precursor concentration at lower precursor concentration range. As shown in FIG. 12C, for nanoparticles synthesized at 0.3M precursor concentration, the peak emission wavelength shows a 37 nm blue shift compared with that of nanoparticles synthesized at a 0.15 M precursor concentration.

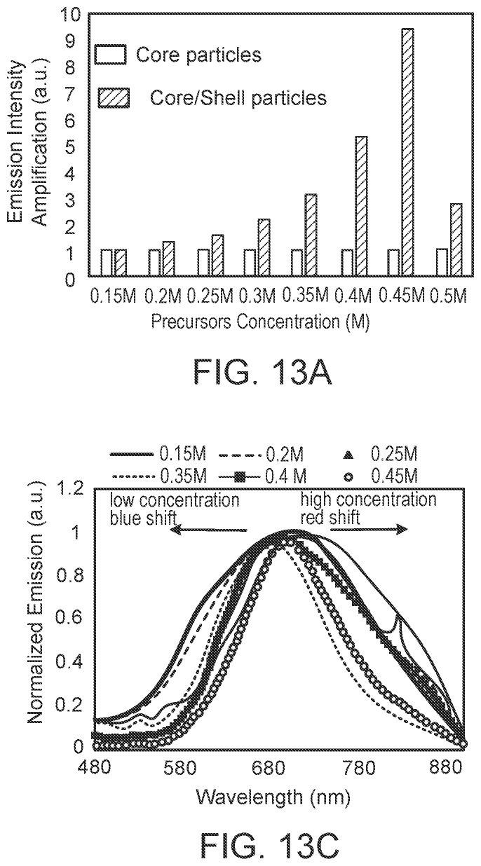

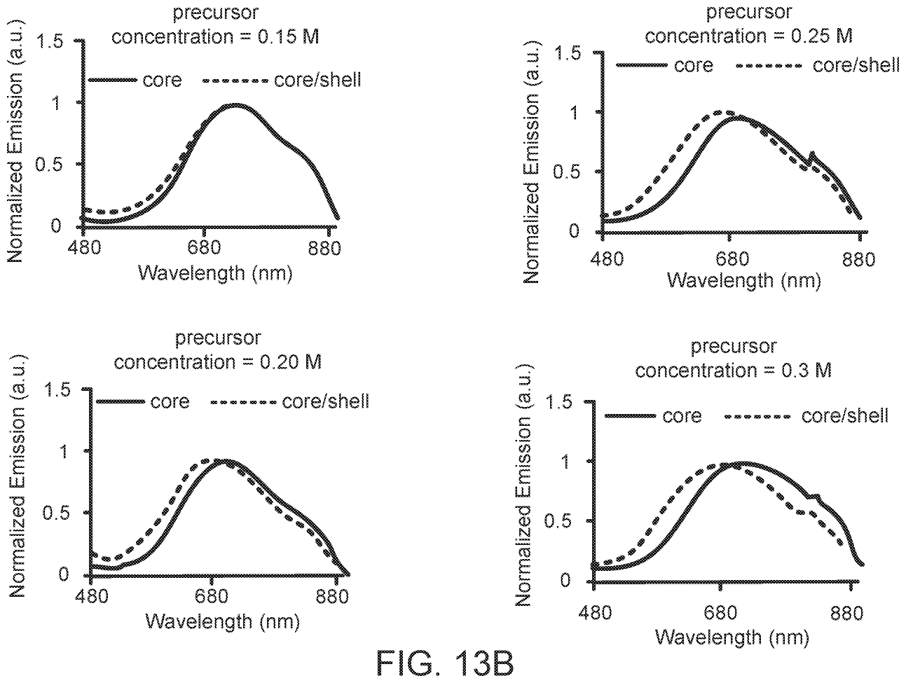

Without being bound by theory, one possible reason for these unexpected phenomena is the saturation or over excess of hydrogen gas contained in the microemulsion template. In order to verify this hypothesis, zinc acetate water solution was added to each sample to react with the excess of hydrogen sulfide to form ZnS shell around the CuInS₂ nanoparticles. The amount of Zn²⁺ added into each sample was equal to the molar amount of Cu⁺¹/In³⁺ precursor contained in the microemulsion. The fluorescence emission of ZnS coated CuInS₂ nanoparticles synthesized under sulfur rich conditions were measured and results are shown in FIGS. 13A-C.

Adding zinc acetate water solution into a microemulsion which contains CuInS₂ core nanoparticles and an excess of free S²⁻ ions can grow ZnS shell above core nanoparticles inside microemulsion directly. Results indicated that coating CuInS₂ core nanoparticles with ZnS significantly increased the florescence emission intensity, especially for core nanoparticles synthesized with high precursor concentration (FIG. 13A). ZnS shell passivation also leads to a blue shift in the peak emission of the CuInS₂ core nanoparticles (FIG. 13B). For ZnS/CuInS₂ core-shell nanoparticles, if the core nanoparticles are synthesized with a low precursor concentration, the peak emission wavelength of the core-shell nanoparticles shows a blue shift with increasing precursor concentration. If the core nanoparticles are synthesized with a high precursor concentration, the peak emission wavelength of the core-shell nanoparticles shows a red shift with increasing precursor concentration (FIG. 13C).

### Example 2—Synthesis of AgInS₂ Quantum Dots

AgInS₂ has a band gap energy similar to that of CuInS₂. Therefore, by adjusting the size and composition of AgInS₂ nanoparticles, AgInS₂ nanoparticles can act as NIR emission materials. AgInS₂ quantum dot cores were synthesized according to the microemulsion template approach described supra.

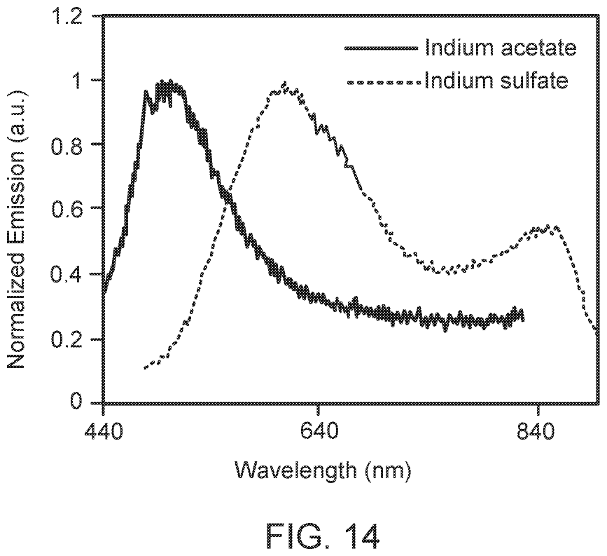

Silver Nitrate (AgNO₃) was used as an Ag¹⁺ precursor, Indium acetate and Indium sulfate were tested to determine which one is able to react with Ag¹⁺ and S²⁻ more efficiently. An Ag¹⁺ precursor bulk solution was prepared by dissolving an appropriate amount of AgNO₃ salt in DI water to reach 1.5M concentration. When indium acetate was used as an In³⁺ precursor, an In³⁺ precursor bulk solution was prepared by dissolving an appropriate amount of In(Ac)₃ in 2N HCL water solution to reach LOM concentration. When indium sulfate was used as an In³⁺ precursor, an In³⁺ precursor bulk solution was prepared by dissolving an appropriate amount of In₂(SO₄)₃ in DI water to reach 1M concentration. Then a 0.2M Ag¹⁺ and In³⁺ solution with an Ag¹⁺/In³⁺ molar ratio 1:1 was prepared by mixing an appropriate volume of each precursor bulk solution and diluting with DI water. The precursor water solution was subsequently mixed with P-xylene and Pluronic® P105 and stirred overnight to form stable microemulsion templates. Solid sodium sulfide powder was used as a S²⁻ precursor. The amount of S²⁻ added was controlled to make the stoichiometric ratio of S²⁻/Ag¹⁺ equal to 2. After adding an appropriate amount of Na₂S powder to the microemulsion which contained Ag¹⁺ and In³, the microemulsion was stirred to allow Na₂S hydrolysis to generate H₂S gas. The H₂S gas diffused into the microemulsion droplets and reacted with Ag⁺¹-In³⁺ precursors to form AgInS₂ nanoparticles. The color of the microemulsion changed from a light grey color to a light yellow-brown or dark red-color, which indicated the formation of AgInS₂ nanoparticles. FIG. 14 shows the emission spectra of AgInS₂ nanoparticles synthesized with 0.2M precursor concentration and In(Ac)₃ and In₂(SO₄)₃ as In³⁺ precursor sources.

For AgInS₂ nanoparticles synthesized with the same Ag¹⁺ and In³⁺ precursor concentration (0.2M), the sample which used In(Ac)₃ as the In³⁺ precursor showed an emission peak around 500 nm, while the sample which used In₂(SO₄)₃ as the In³⁺ precursor showed two emission peaks, one around 600 nm and the other around 850 nm. For nanoparticles synthesized using In(Ac)₃ as the In³⁺ precursor, apparently due to presence of hydrogen chloride acid inside the microemulsion droplets for dissolving In(Ac)₃, the as-prepared AgInS₂ nanoparticles decomposed very fast as losing of S²⁻ ions. It was difficult to form an Ag—S donor-acceptor recombination conductive band gap, which is the major contributor to near infrared emission. For samples synthesized using In₂(SO₄)₃ as the In³⁺ precursor, the Ag—S conductive band gap was partially formed, which was indicated with the NIR emission around 850 nm.

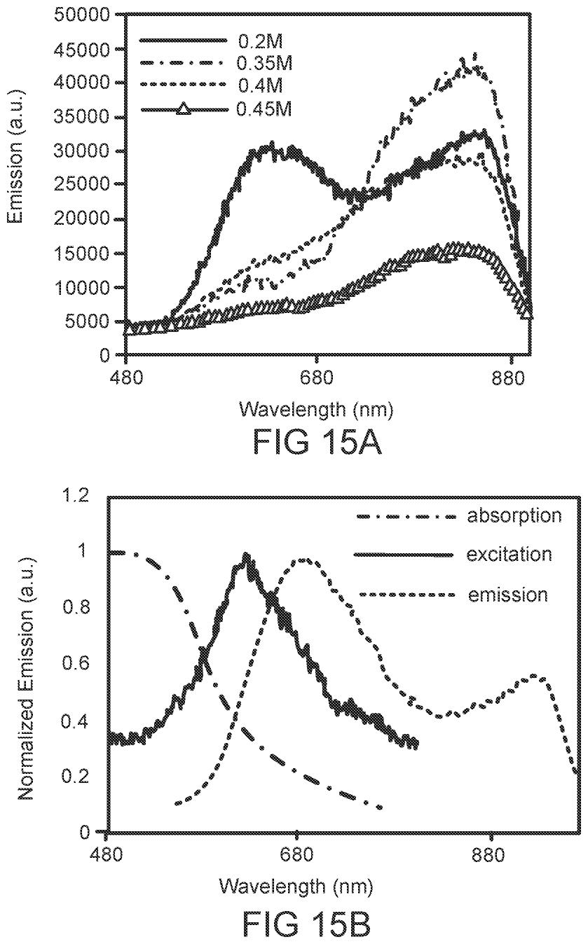

Experiments were subsequently performed by using In₂(SO₄)₃ as the In³⁺ precursor but with increasing precursor concentration. The Ag¹⁺ ion precursor, S²⁻ ion precursor, and experimental condition were kept the same. The optical spectra for the as-prepared core AgInS₂ nanoparticles are shown in FIGS. 15A-B. FIG. 15A shows emission spectra for core AgInS₂ nanoparticles synthesized with different precursor concentrations and FIG. 15B shows the normalized absorption, excitation, and emission spectra for core AgInS₂ nanoparticles synthesized with a precursor concentration of 0.2M. As the precursor concentration increases, the Ag—S donor-acceptor recombination NIR emission peak becomes dominant. The emission intensity initially increased with higher precursor concentration but began to decrease with further increase in precursor concentration. The synthesis performed for these experiments used Na₂S solid powder as the S²⁻ precursor source, and the amount of S²⁻ added was stoichiometric. Due to limitations of Na₂S hydrolysis, the amount of S²⁻ ions contributed to the nanoparticle synthesis was not stoichiometric, but rather was less than the stoichiometric ratio of 2. Thus, synthesis occurred with a deficiency of S²⁻ ions. The kinetic speed of In³⁺ ions binding with S²⁻ ions is favored and faster compared to the binding with Ag¹⁺ ions. Increasing precursor concentration first accelerates the Ag⁺—S²⁻ conduction bond formation, which results in the NIR emission peak becoming dominant and stronger. However, higher concentration generally produces larger sized nanoparticles, which will involve more surface traps and defects and thereby leads to lower emission intensity.

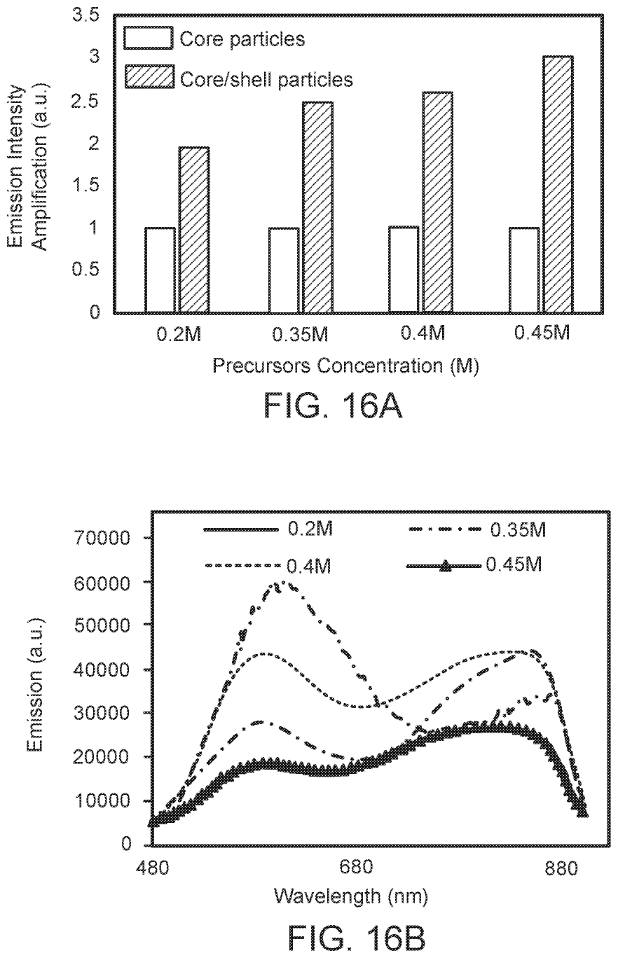

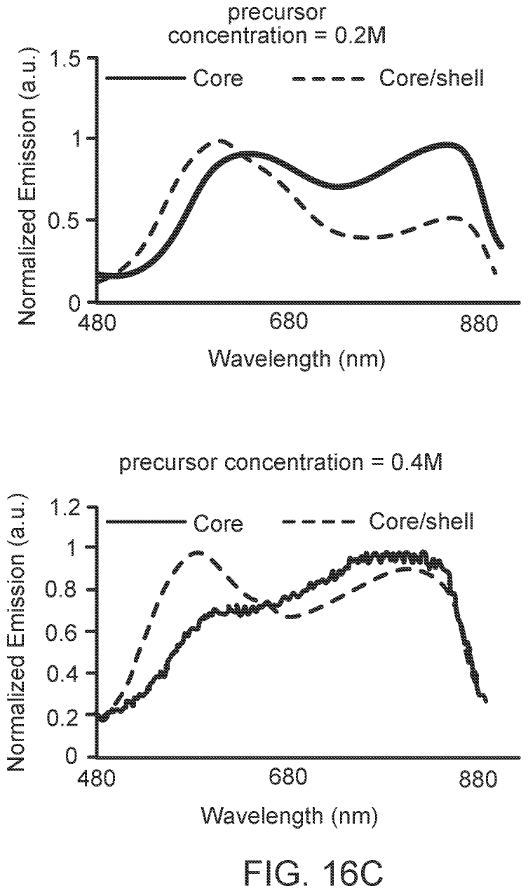

To improve the NIR emission intensity, attempts were made to grow a ZnS shell directly above “naked” AgInS₂ core nanoparticles inside the microemulsion. 10 mL of as-prepared core AgInS₂ nanoparticles synthesized with various precursor concentrations and passivated by microemulsion micelles was used as the base for grown of ZnS shells. Sodium sulfide water solution (with concentration of 2M) was added to the microemulsion and the samples were stirred for at least 2 hours to allow a sufficient amount of S²⁻ ions be generated inside the microemulsion droplets. The amount of sodium sulfide added was equal to the molar amount of Ag and In precursors contained in the as-prepared core nanoparticles-microemulsion. As the microemulsion color became darker, indicating generation of H₂S gas inside the microemulsion droplets, an equal molar amount of zinc acetate (1.5M zinc acetate water solution) was added and the mixture was continuously stirred overnight to complete the shell growth. The fluorescence emission of core/shell AgInS₂/ZnS core-shell nanoparticles synthesized using with various precursor concentrations in microemulsion were measured and the results are illustrated in FIGS. 16A-C.

Referring to FIG. 16A, consistent with the results seen for CuInS₂ nanocrystals, coating AgInS₂ core nanoparticles inside microemulsion directly with a ZnS shell increased the emission intensity of the core nanoparticles. The level of emission intensity amplification for core nanoparticles synthesized with higher precursor concentration is stronger than that of nanoparticles synthesized with relatively lower precursor concentration. Shelling core nanoparticles with ZnS shell increased the emission intensity but also weakened the Ag—S donor-acceptor recombination NIR emission for nanoparticles synthesized with lower precursor concentration. Moreover, surface passivation made the In—S recombination emission become stronger (as shown in the emission spectra of FIG. 16B, which shows emission spectra for AgInS₂ core/shell nanoparticles synthesized with different precursor concentrations). Again consistent with the results seen for CuInS₂ nanocrystals, coating AgInS₂ core nanoparticles with ZnS shells resulted in a blue shift of the peak emission wavelength (FIG. 16C).

Without being bound by theory, one possible reason for these observed phenomena is a deficiency of S²⁻ ions. Synthesized core AgInS₂ nanocrystals with excess of S²⁻ ions may avoid the domination of formation of In—S recombination emission but make Ag—S recombination NIR become dominant for fixed Ag/In ratio. Experiments synthesizing AgInS₂ nanoparticles with a saturation of S²⁻ ions were performed to verify the hypothesis.

For this group of experiments, AgNO₃ was used as the Ag¹⁺ precursor source, In₂(SO₄)₃ was used as the In³⁺ precursor source, and H₂S gas was used as the S²⁻ precursor source. AgInS₂ core nanoparticles were synthesized with different molar precursor concentrations from 0.15M to 0.6M by following the microemulsion template approach described here.

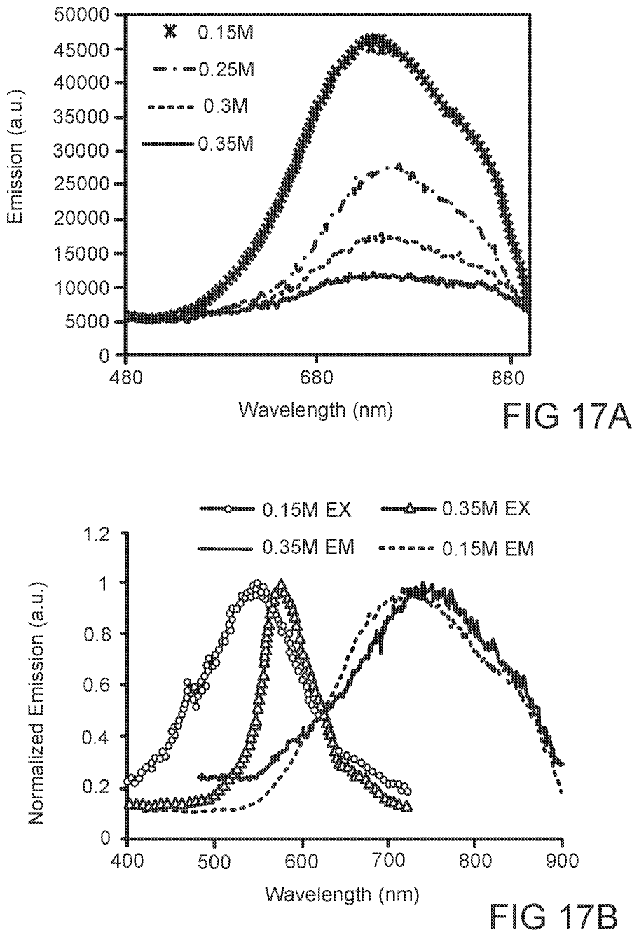

An Ag⁺ precursor bulk solution was prepared by dissolving an appropriate amount of AgNO₃ salt in DI water to reach 1.5M concentration. An In³⁺ precursor bulk solution was prepared by dissolving an appropriate amount of In₂(SO₄)₃ in DI water to reach 1M concentration. Then 0.15M, 0.25M, 0.3M, 0.35M, 0.45M, 0.5M, 0.55M and 0.6M Ag¹⁺ and In³⁺ solutions with Ag¹⁺/In³⁺ molar ratio 1:1 were prepared by mixing an appropriate volume of each precursor bulk solution and diluting with DI water. The precursor water solution was subsequently mixed with P-xylene and Pluronic® P105 and stirred overnight to form stable microemulsion templates. Hydrogen sulfide gas was introduced into a glass bottle reactor which contained the stable microemulsion template in order to be absorbed by the microemulsion and then react with Ag¹⁺ and In³⁺ ions to form AgInS₂ nanoclusters inside each microemulsion droplet. The hydrogen sulfide gas was produced by a house-made gas reactor. The glass bottle containing microemulsion templates with Ag¹⁺ and In¹⁺ ions was put into a secondary container which can be sealed without leaking. A small vial which contained an appropriate amount of iron sulfide (FeS) solid powder was also put into the same container. The secondary container was sealed and 5M hydrogen sulfate acid water solution was injected drop-wise, slowly and continuously, into the small vial which contained FeS to allow FeS react with H₂SO₄ to produce H₂S gas. The generated H₂S gas was absorbed by the microemulsion templates and the gas molecules subsequently diffused into the microemulsion droplets to react with Ag¹⁺ and In³⁺ ions. The color of the microemulsion changed from a light grey color into a dark red or dark brown color, depending on the precursor concentration, which indicated the formation of CuInS₂ nanoparticles. For each sample, the reaction was performed for 5 hours to complete the synthesis. The photoluminescence properties of as-prepared AgInS₂ core nanoparticles in microemulsion were measured and the results are illustrated in FIGS. 17A-B.

These results confirmed that AgInS₂ core nanoparticle synthesis in microemulsion templates prefers rich sulfur experimental condition. The Ag—S donor-acceptor recombination NIR emission is dominant for AgInS₂ nanoparticles synthesis with an excess of H₂S existing in the microemulsion template. The peak emission wavelength of the as-prepared core nanoparticles showed a red shift with increasing the precursor concentration, with both excitation and emission scanning confirming the trend. By changing the precursor concentration from 0.15M to 0.6M, the peak emission wavelength of the core AgInS₂ nanoparticles shifts from ˜730 nm up to 820 nm. Core AgInS₂ nanoparticles synthesized with lower precursor concentration also exhibited very strong emission compared with those synthesized with high precursor concentration.

The as-prepared core AgInS₂ nanoparticles synthesized under rich S²⁻ conditions were coated with a thin ZnS shell directly within the microemulsion droplets to verify whether the coating would passivate the surface of the core nanoparticles and thereby increase the brightness of the core nanoparticles.

Due to the large excess of H₂S in the as-prepared core nanoparticle microemulsion, ZnS shell growth was performed by adding Zn²⁺ precursors only instead of both Zn²⁺ and S²⁻ precursors. 10 mL of as-prepared core AgInS₂ nanoparticles synthesized with various precursor concentrations in rich H₂S and passivated by microemulsion micelles was used as a base for growth of ZnS shells. A 1.5M Zn(Ac)₂ water solution was used as the Zn²⁺ precursor source. The amount of zinc acetate added was equal to the molar amount of Ag and In precursor contained in the as-prepared core nanoparticle microemulsion. The solution of the core nanoparticle microemulsion with the added Zn(Ac)₂ water solution was stirred overnight to complete the shell growth.

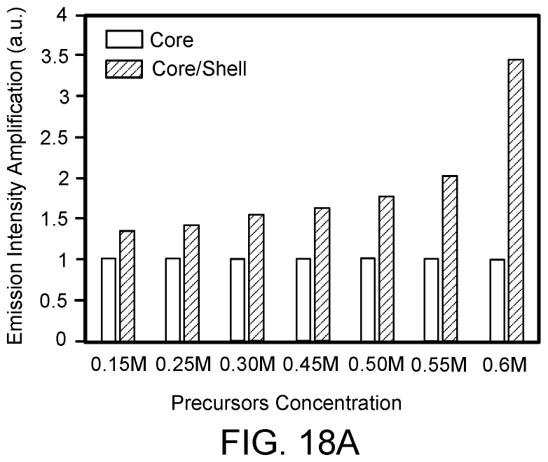

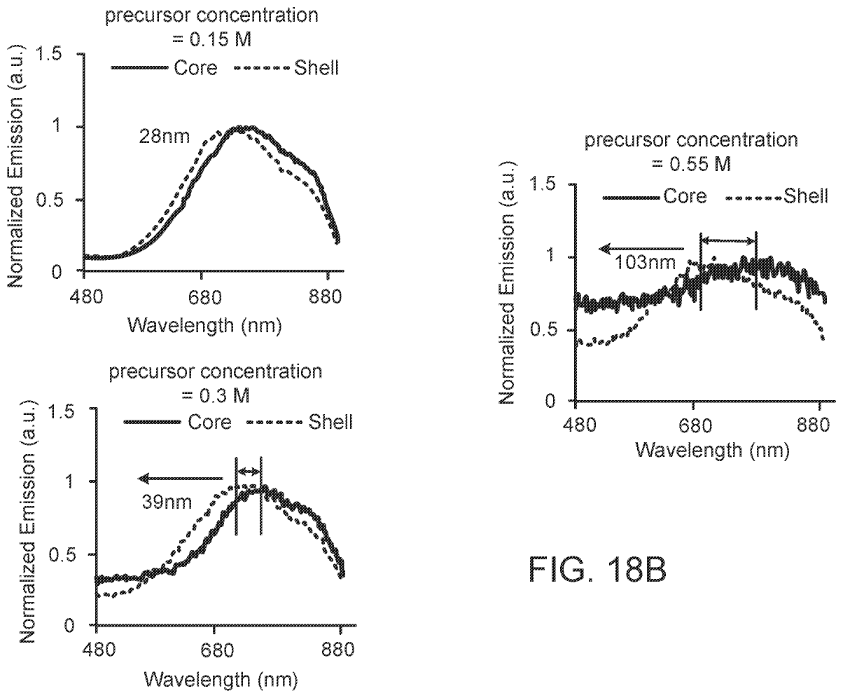

The fluorescence emission of core/shell AgInS₂/ZnS nanoparticles synthesized in microemulsion with an excess of S²⁻ and with various precursor concentrations was measured and the results are illustrated in FIG. 18A-B.

Referring to FIG. 18A, consistent with the results seen for nanoparticles synthesized under an S²⁻ deficient condition, these results indicated that for AgInS₂ core nanoparticles synthesized with an excess of S²⁻, coating the nanoparticles with ZnS increased the florescence emission intensity, especially for core nanoparticles synthesized with high precursor concentration. However, the degree of emission intensity enhancement was not as strong as that of particles synthesized under an S²⁻ deficient condition with low precursor concentration. ZnS shell passivation also leads to a blue shift in the peak emission wavelength, and with increasing precursor concentration, the ZnS coating can result in up to a 100 nm blue shift in the peak emission wavelength (FIG. 18B).

### Example 3—Coating Study for AgInS₂ Core Nanoparticles Synthesized with an Excess of S²⁻

To investigate the effect of ZnS shell coating on “naked” AgInS₂ nanoparticles synthesized in microemulsion with an excess of S²⁻, 80 mL of AgInS₂ core nanoparticles in microemulsion with 0.4M precursor concentration were synthesized according to the microemulsion template assisted method described here. Silver Nitrate (AgNO₃) and Indium Sulfate (In₂(SO₄)₃) salts were used as Ag¹⁺ and In³⁺ precursor sources, respectively, and hydrogen sulfide gas was used as the S²⁻ precursor source. 1.5M silver nitrate and 1M Indium sulfate concentrated bulk solutions were prepared by dissolving an appropriate amount of the inorganic salt in DI water. A 0.4M Ag¹⁺ and In³⁺ solution with an Ag¹⁺/In³⁺ molar ratio of 1:1 was prepared by mixing an appropriate volume of each precursor bulk solution and diluting with DI water. The precursor water solution was subsequently mixed with P-xylene and Pluronic® P105 and stirred overnight to form stable microemulsion templates. Hydrogen sulfide gas was introduced into a glass bottle reactor which contained the stable microemulsion template in order to be absorbed by the microemulsion and then react with Ag¹⁺ and In³⁺ ions to form AgInS₂ nanoclusters inside each microemulsion droplet. The color of the microemulsion changed from a light grey color to a dark brown color, indicating the formation of AgInS₂ nanocrystals. The as-prepared AgInS₂ nanoparticles in microemulsion were stored in dark condition for one week before performing the shell coating study in order to stabilize the core nanoparticles.

Five samples of nanoparticles in microemulsion were prepared for the shelling condition investigation. Each sample contained 10 mL as-prepared, one week matured AgInS₂ nanoparticles in microemulsion. Five shell coatings were performed as follows. For each sample, the as-prepared core dots in microemulsion was used except for Shell #5. For Shell #5, the clear microemulsion layer, which did not contain a large amount of excess sulfur, was collected for use in the shell coating process.

Shell #1: a molar amount of sodium sulfide (2M water solution) equal to the molar amount of Ag and In precursors contained in the as-prepared AgInS₂ nanoparticles in microemulsion was added to the emulsion. The mixture was stirred at room temperature for 2 hours, then an equal molar amount of zinc acetate (1.5M zinc acetate water solution) was added and the mixture was continuously stirred overnight.

Shell #2: an equal molar amount of zinc acetate only (1.5M water solution) was added to the nanoparticles in microemulsion and the sample was stirred overnight.

Shell #3: an equal molar amount of zinc acetate only (dry solid chemical) was added to the nanoparticles in microemulsion and the sample was stirred overnight.

Shell #4: a double molar amount of zinc acetate only (dry solid chemical) was added to the nanoparticles in microemulsion and the sample was stirred overnight.

Shell #5: a double molar amount of zinc acetate only (dry solid chemical) was added to the nanoparticles in microemulsion and the sample was stirred overnight.

The fluorescence properties of all shell samples were tested, and the un-coated core nanoparticles in microemulsion were used for comparison.

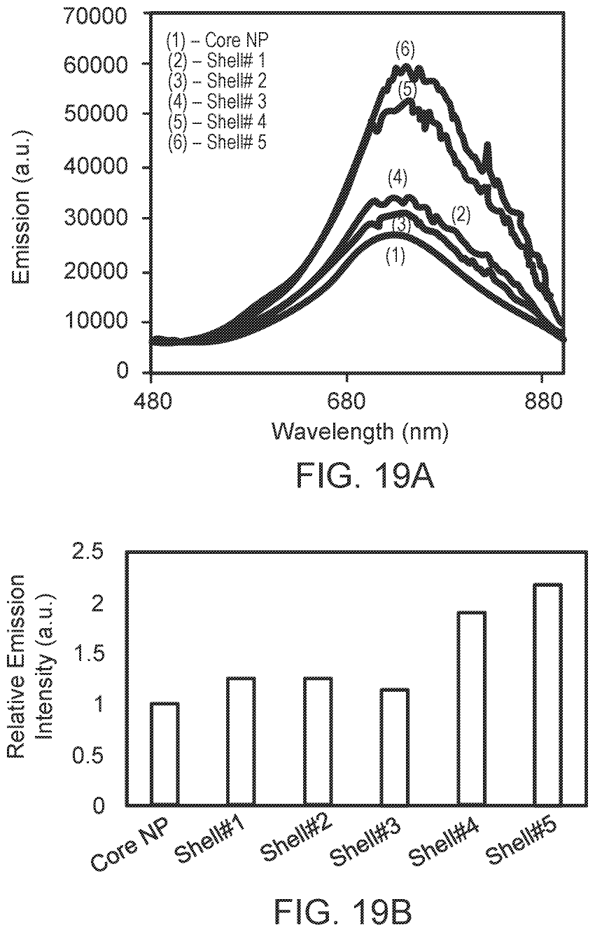

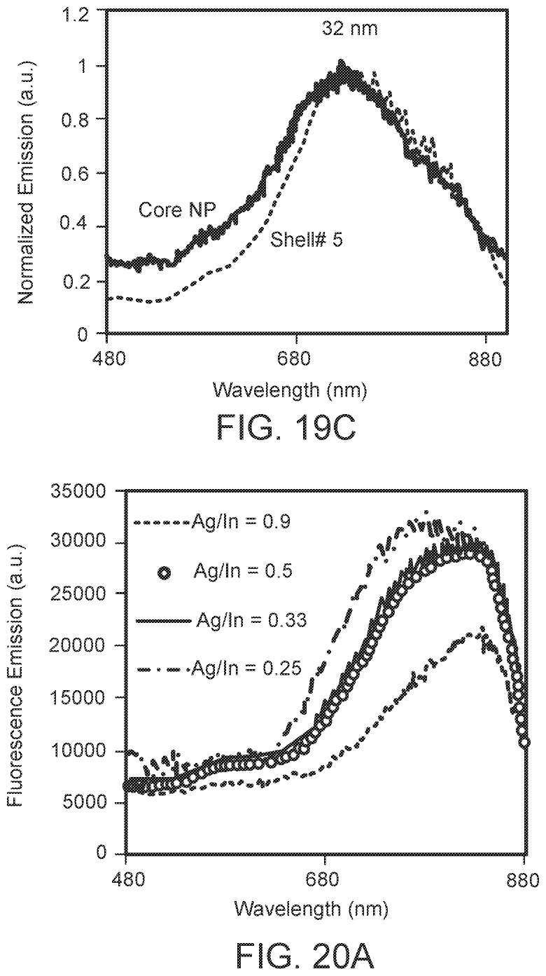

Referring to FIGS. 19A-19C, the results indicated that due to the large excess of hydrogen sulfide absorbed by the microemulsion, only the addition of zinc salt was sufficient to form a ZnS shell on the nanoparticles. Samples with and without the addition of sulfur precursor generated core-shell nanoparticles with almost identical fluorescent optical properties. Moreover, the physical status (e.g., solution versus dry solid) of the zinc precursor had no substantive effect on the coating, although it is possible that a large volume of water solution may interfere with the stability of the microemulsion nanostructure. All shell coating samples showed stronger emission intensity compared with core nanoparticles. Samples with double the amount of zinc precursor grew thicker zinc sulfide shells and thus had significantly higher emission intensity.

Notably, as illustrated in FIG. 19C, if the microemulsion of core nanoparticles did not contain a large excess of free sulfur, for the same amount of zinc precursor, the emission intensity grew stronger and a red shift in the peak emission wavelength was observed. Without being bound by theory, it is believed that some of the shell material diffused into the AgInS₂ crystalline structure and formed alloyed structure having a different bandgap energy level.

### Example 4—Synthesis of AgInS₂ Nanoparticles with Various Ion Ratios

Since the major mechanism for NIR emission of I-III-VI type ternary nanoparticles comes from donor-acceptor recombination, the binding capability of different donor ions with acceptor ions is important. Therefore, changing the precursor ratio in the synthesis of I-III-VI nanoparticles may have a significant effect on the optical properties of the ternary nanoparticles. A group of experiments were performed in which AgInS₂ nanoparticles were synthesized according to the microemulsion template method described supra and using various Ag/In precursor ratios.

20 mL of AgInS₂ core nanoparticles in microemulsion with 0.4M precursor concentration and different ion ratios were prepared using AgNO₃ as the Ag¹⁺ precursors source, In₂(SO₄)₃ as the In³⁺ precursor source, and sodium sulfide powder as the S²⁻ precursor source. 1.5M silver nitrate and 1M Indium sulfate concentrated bulk solutions were prepared by dissolving an appropriate amount of inorganic salt in DI water. Solutions containing 0.4M In³⁺ precursor and various Ag¹⁺ concentration with Ag¹⁺/In³⁺ molar ratio (specifically, 0.9:1, 0.5:1, 0.3:1, and 0.25:1) were prepared by mixing an appropriate volume of each precursor bulk solution and diluting with DI water. The precursor water solution was subsequently mixed with P-xylene and Pluronic® P105 and stirred overnight to form stable microemulsion templates. An appropriate amount of Na₂S powder was added to each sample and continuously stirred for 8 hours. The amount of Na₂S was added to each sample was controlled to maintain a stoichiometric ratio of In/S=1.2. The color of the microemulsion emulsion changed from a light grey color to a dark yellow color for samples with low Ag⁺/In³⁺ ratio and to a dark brown color for samples with higher Ag¹⁺/In³⁺ ratio.

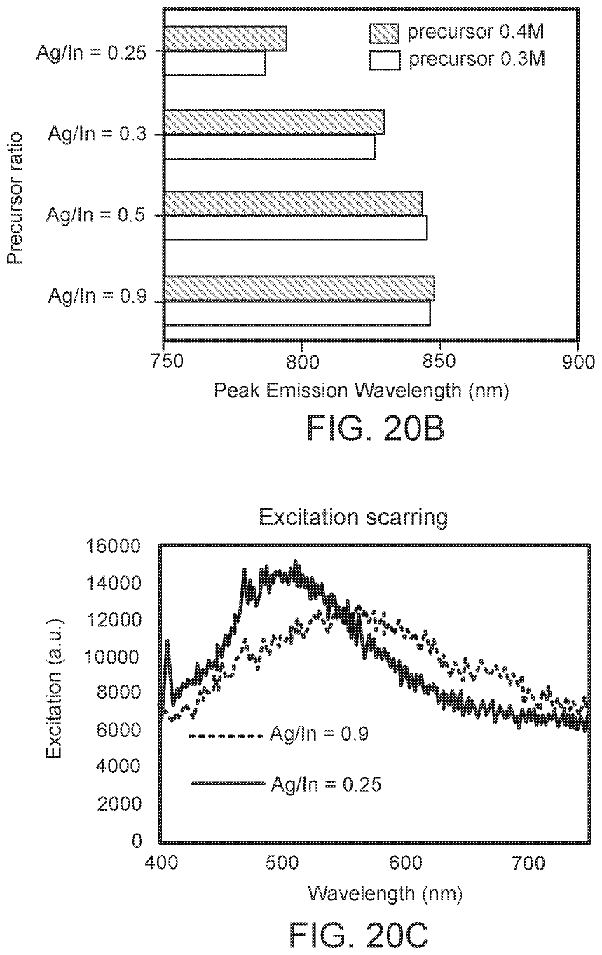

The fluorescence emission spectra for AgInS₂ core nanoparticles synthesized with various Ag¹⁺/In³⁺ ratios are shown in FIG. 20A. The emission intensity of the sample with an Ag¹⁺/In³⁺ ratio of 0.25 is two times stronger than the emission intensity of the sample with Ag¹⁺/In³⁺=0.9. Reducing the Ag ion ratio also results in AgInS₂ core nanoparticles that emit fluorescence at higher energy. The trend of reducing Ag ions in AgInS₂ core nanoparticles leading to a blue shift in the peak emission wavelength was not dependent on the In precursor concentration. Experiments with 0.3M In precursor concentration show substantially identical results as those with 0.4M In precursor concentration (FIG. 20B). Excitation scanning confirmed that reducing Ag¹⁻ ion composition in AgInS₂ nanocrystals produces nanoparticles that emit light at higher energy levels (FIG. 20C).

These experiments reveal that precursor concentration, precursor ratios, and shell growth affect the emission spectrum of the quantum dot cores significantly. With the experimental conditions described above, the emission wavelengths of the quantum dot cores reached a maximum peak emission wavelength of 840 nm. These experiments also demonstrated that larger size CuInS₂ and AgInS₂ quantum dot cores have weaker emission intensity than smaller quantum dots. Annealing and further shell coating of the core quantum dots can be performed to enhance the quantum yield.

Surface modification of core or core/shell nanoparticles with suitable surface ligands can be performed, e.g., based on desired functionality for the nanoparticles.

Particular embodiments of the subject matter have been described. Other embodiments are within the scope of the following claims.

1. A method for making ternary core-shell semiconductor nanoparticles, the method comprising:
providing an emulsion comprising droplets dispersed in a continuous phase of a non-polar solvent, in which the droplets comprise a solution of ions of a Group I element and ions of a Group III element in a polar solvent, and in which the droplets are encapsulated by an interfacially active material;
exposing the emulsion to ions of a Group VI element to cause the ions of a Group VI element to react with the ions of the Group I element and ions of the Group III element in the droplets to form nanoparticles in the droplets;
reacting the nanoparticles in the droplets with a first precursor to grow a shell on the nanoparticles, thereby forming core-shell nanoparticles;
extracting the core-shell nanoparticles from the emulsion;
thermally annealing the core-shell nanoparticles; and
reacting the annealed core-shell nanoparticles with a second precursor to further grow the shell on the nanoparticles, thereby forming ternary core-shell semiconductor nanoparticles.

2. The method of claim 1, comprising dissolving a first reactant and a second reactant in the polar solvent to form the solution of the ions of a Group I element and the ions of a Group III element,
in which the first reactant comprises a Group I element-containing compound and the second reactant comprises a Group III element-containing compound.

3. The method of claim 2, in which the first reactant comprises a salt of the Group I element.

4. (canceled)

5. (canceled)

6. The method of claim 2, comprising adjusting the pH of the polar solvent to dissolve the first reactant and the second reactant in the polar solvent.

7. The method of claim 2, in which dissolving the first reactant and the second reactant in the polar solvent comprises:
dissolving the first reactant in a basic or acidic solution of the polar solvent;
dissolving the second reactant in an acidic or basic solution of the polar solvent; and
combining the solution with the dissolved first reactant and the solution with the dissolved second reactant to form the solution of the ions of a Group I element and the ions of a Group III element.

8. The method of claim 2, in which dissolving the first reactant and the second reactant in the polar solvent comprises dissolving the first reactant and the second reactant in a neutral polar solvent.

9. The method of claim 1, in which the ions of the Group I element comprise ions of Cu or Ag and in which the ions of the Group III element comprise ions of In or Ga.

10. (canceled)

11. The method of claim 1, in which the interfacially active material comprises an amphiphilic block copolymer, a surfactant, a water-dispersible polymer, an amphiphilic molecule, a solid particle, or a solvent-swollen particle.

12. The method of claim 1, in which the nanoparticles have a composition ABX_{y}, where A is the Group I element, B is the Group III element, and X is the Group VI element.

13. The method of claim 1, in which exposing the emulsion to ions of the Group VI element comprises contacting the emulsion with a gas containing a Group VI element-containing compound, a solid chemical containing a Group VI element-containing compound, or a solution containing a Group VI element containing compound.

14. (canceled)

15. (canceled)

16. The method of claim 1, in which the Group VI element comprises S, Se, or Te.

17. The method of claim 1, in which reacting the nanoparticles in the droplets with the first precursor comprises exposing the emulsion to a precursor to the shell, in which the precursor to the shell comprises a precursor to ZnS or ZnSe.

18. (canceled)

19. (canceled)

20. The method of claim 1, comprising functionalizing the core-shell nanoparticles with hydrophilic surface ligands.

21. The method of claim 1, comprising:
functionalizing the core-shell nanoparticles with hydrophobic surface ligands; and
exchanging the hydrophobic surface ligands for hydrophilic surface ligands following growth of the shell on the nanoparticles.

22. (canceled)

23. The method of claim 1, in which thermally annealing the core-shell nanoparticles comprises annealing the core-shell nanoparticles in a batch process.

24. The method of claim 1, in which reacting the annealed core-shell nanoparticles with the second precursor comprises reacting the annealed core-shell nanoparticles with Zn²⁺ ions.

25. The method of claim 1, in which the ternary core-shell semiconductor nanoparticles have a fluorescence emission wavelength of between 650 nm and 840 nm and a quantum yield of at least 40% in an aqueous solvent.

26. (canceled)

27. (canceled)

28. A method for making ternary core-shell semiconductor nanoparticles, the method comprising:
providing an emulsion comprising droplets dispersed in a first solvent, in which the droplets comprise a solution of ions of a Group I element and ions of a Group III element in a second solvent, and in which the droplets are encapsulated by an interfacially active material, and in which the first solvent is immiscible with the second solvent;
exposing the emulsion to ions of a Group VI element to cause the ions of the Group VI element to react with the ions of the Group I element and ions of the Group III element in the droplets to form nanoparticles in the droplets;
reacting the nanoparticles in the droplets with a first precursor to grow a shell on the nanoparticles, thereby forming core-shell nanoparticles;
extracting the core-shell nanoparticles from the emulsion.

29-40. (canceled)

41. A method for making ternary core-shell semiconductor nanoparticles, the method comprising:
extracting core-shell nanoparticles from an emulsion comprising droplets of a first solvent dispersed in a second solvent, in which the nanoparticles are contained in the droplets and in which the droplets are encapsulated by an interfacially active material, and in which the nanoparticles comprise a core coated with a shell, in which the core of the core-shell nanoparticles has a composition ABX_{y}, where A is a Group I element, B is a Group III element, and X is a Group VI element;
thermally annealing the core-shell nanoparticles; and
reacting the annealed core-shell nanoparticles with a precursor to increase the thickness of the shell of the nanoparticles.

42-48. (canceled)

49. A composition comprising:
an emulsion containing droplets of a first solvent dispersed in a second solvent;
an interfacially active material encapsulating each droplet of the emulsion; and
a core-shell nanoparticle contained in each of at least some of the droplets, in which the core of each core-shell nanoparticles has a composition ABXy, where A is a Group I element, B is a Group III element, and X is a Group VI element.

50-58. (canceled)
